(19) United States
(12) Patent Application Publication
(10) Pub. No.: US 2018/0033399 A1
(43) Pub. Date: Feb. 1, 2018

(54) ELECTRONIC DEVICE AND DRIVING METHOD THEREOF

(71) Applicant: Semiconductor Energy Laboratory Co., Ltd., Atsugi-shi (JP)

(72) Inventors: Susumu KAWASHIMA, Atsugi (JP); Ryo HATSUMI, Hadano (JP); Yusuke NISHIDO, Atsugi (JP); Daisuke KUBOTA, Atsugi (JP)

(73) Assignee: Semiconductor Energy Laboratory Co., Ltd.

(21) Appl. No.: 15/657,279

(22) Filed: Jul. 24, 2017

(30) Foreign Application Priority Data
Jul. 29, 2016 (JP) 2016-149748

(51) Int. Cl. G09G 5/10; G09G 3/3225; G09G 3/36; H01L 27/32; G02F 1/1335

(52) U.S. Cl. CPC G09G 5/10; H01L 27/3232; G02F 1/133553; H01L 27/3227; G09G 3/3648; G09G 3/3225; H01L 27/3244; G02F 1/1368

(57) ABSTRACT

An electronic device which can display an image with the viewing angle dependence reduced is provided. A driving method of an electronic device including a display portion and a position detection sensor is provided. The display portion includes a first display element and a second display element. The first display element is configured to reflect visible light, and the second display element is configured to emit visible light. The display portion is configured to display an image using one or both of first light reflected by the first display element and second light emitted by the second display element. The position detection sensor is configured to detect a position of a user. When the display portion displays the image using both the first light and the second light, an amount of the second light is adjusted in accordance with an angle from which the display portion is viewed by the user.

### BACKGROUND OF THE INVENTION

### 1. Field of the Invention

One embodiment of the present invention relates to a method for driving an electronic device including a display device. Furthermore, one embodiment of the present invention relates to an electronic device including a display device.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof.

### 2. Description of the Related Art

Portable information terminals typified by smartphones and tablet terminals have been actively developed. These portable information terminals are required to be lightweight and small, for example.

In particular, development of a wearable electronic device (also referred to as a wearable device) has been actively carried out recently. Examples of the wearable device include a watch-type device worn on an arm, a glasses-like device worn on a head, and a necklace-type device worn on a neck. For example, a watch-type device includes a small-sized display instead of a conventional watch dial to provide the user with various information in addition to the time. Such wearable devices have attracted attention to the medical use, the use for self-health management, or the like and have been increasingly put into practical use.

Examples of the display device include, typically, a light-emitting device including a light-emitting element such as an organic electroluminescent (EL) element or a light-emitting diode (LED), a liquid crystal display device, and an electronic paper performing display by an electrophoretic method or the like.

Patent Document 1 discloses a flexible light-emitting device using an organic EL element.

### REFERENCE

### Patent Document

[Patent Document 1] Japanese Published Patent Application No. 2014-197522

### SUMMARY OF THE INVENTION

An object of one embodiment of the present invention is to provide an electronic device which can display an image with the viewing angle dependence reduced. Another object of one embodiment of the present invention is to provide an electronic device which can display an image with high display quality.

Another object of one embodiment of the present invention is to provide an electronic device having high visibility regardless of the brightness of external light. Another object of one embodiment of the present invention is to provide an electronic device with low power consumption. Another object of one embodiment of the present invention is to provide an electronic device which can display both a smooth moving image and an eye-friendly still image. Another object of one embodiment of the present invention is to provide a novel electronic device.

One embodiment of the present invention is a driving method of an electronic device including a display portion and a position detection sensor. The display portion includes a first display element and a second display element. The first display element is configured to reflect visible light, and the second display element is configured to emit visible light. The display portion is configured to display an image using one or both of first light reflected by the first display element and second light emitted by the second display element. The position detection sensor is configured to detect a position of a user. When the display portion displays the image using both the first light and the second light, an amount of the second light is adjusted in accordance with an angle from which the display portion is viewed by the user.

One embodiment of the present invention is a driving method of an electronic device including a display portion, a position detection sensor, and an illuminance sensor. The display portion includes a first display element and a second display element. The first display element is configured to reflect visible light, and the second display element is configured to emit visible light. The display portion is configured to display an image using one or both of first light reflected by the first display element and second light emitted by the second display element. The position detection sensor is configured to detect a position of a part of a user. The illuminance sensor is configured to measure an illuminance of external light. When the display portion displays the image using both the first light and the second light, an amount of the second light is adjusted in accordance with an angle from which the display portion is viewed by the user and the illuminance of the external light.

The driving method of the above-described electronic device, in which the electronic device includes a housing and in which the display portion and the position detection sensor are positioned on a first surface of the housing, is also one embodiment of the present invention.

The driving method of the above-described electronic device, in which the electronic device includes a housing and in which the display portion, the position detection sensor, and the illuminance sensor are positioned on a first surface of the housing, is also one embodiment of the present invention.

The driving method of the above-described electronic device, in which the first display element is a reflective liquid crystal element and in which the second display element is a light-emitting element, is also one embodiment of the present invention.

Furthermore, the driving method of the above-described electronic device, in which the amount of the second light is adjusted by an adjustment of data amplitude, is also one embodiment of the present invention.

One embodiment of the present invention is an electronic device including a display portion, a position detection sensor, and a housing. The display portion and the position detection sensor are provided on a first surface of the housing. The display portion includes a first display element and a second display element. The first display element is configured to reflect visible light, and the second display element is configured to emit visible light. The display portion is configured to display an image using one or both of first light reflected by the first display element and second light emitted by the second display element. The position detection sensor is configured to detect a position of a part of a user.

Moreover, the electronic device further including an illuminance sensor which is positioned on the first surface of the housing is also one embodiment of the present invention.

Furthermore, the electronic device in which the first display element is a reflective liquid crystal element and the second display element is a light-emitting element, is also one embodiment of the present invention.

The electronic device in which, when the display portion displays the image using both the first light and the second light, an amount of the second light is adjusted in accordance with data detected by the position detection sensor, is also one embodiment of the present invention.

With one embodiment of the present invention, an electronic device which can display an image with the viewing angle dependence reduced can be provided. Furthermore, an electronic device which can display an image with high display quality can be provided.

With one embodiment of the present invention, an electronic device having high visibility regardless of the brightness of external light can be provided. An electronic device with low power consumption can be provided. An electronic device which can display both a smooth moving image and an eye-friendly still image can be provided. A novel electronic device can be provided.

### BRIEF DESCRIPTION OF THE DRAWINGS

In the accompanying drawings:

FIG. 1 illustrates an electronic device;

FIGS. 2A1, 2A2, 2B1, and 2B2 illustrate usage states of an electronic device;

FIG. 3 shows a driving method of an electronic device;

FIG. 4 illustrates an electronic device;

FIG. 5 shows a driving method of an electronic device;

FIG. 6 is a block diagram illustrating an example of a display device;

FIGS. 7A to 7C illustrate an example of a pixel unit;

FIGS. 8A to 8C illustrate examples of a pixel unit;

FIGS. 9A, 9B1, 9B2, 9B3, and 9B4 illustrate an example of a display device and examples of pixels;

FIG. 10 is a circuit diagram illustrating an example of a pixel circuit of a display device;

FIG. 11A is a circuit diagram illustrating an example of a pixel circuit of a display device, and FIG. 11B illustrates an example of a pixel;

FIG. 12 is a perspective view illustrating an example of a display device;

FIG. 13 is a cross-sectional view illustrating an example of a display device;

FIG. 14 is a cross-sectional view illustrating an example of a display device;

FIGS. 15A to 15E are cross-sectional views illustrating examples of a transistor;

FIGS. 16A to 16D are cross-sectional views illustrating an example of a manufacturing method of a display device;

FIGS. 17A to 17C are cross-sectional views illustrating an example of a manufacturing method of a display device;

FIGS. 18A and 18B are cross-sectional views illustrating an example of a manufacturing method of a display device;

FIGS. 19A and 19B are cross-sectional views illustrating an example of a manufacturing method of a display device;

FIGS. 20A to 20C show viewing angle dependence of a display device measured in Example;

FIGS. 21A to 21C show viewing angle dependence of a display device measured in Example;

FIGS. 22A to 22C show viewing angle dependence of a display device measured in Example; and

FIGS. 23A to 23C are graphs showing data amplitudes of a display device in Example.

### DETAILED DESCRIPTION OF THE INVENTION

Embodiments will be described in detail with reference to drawings. Note that the present invention is not limited to the following description, and it is easily understood by those skilled in the art that various changes and modifications can be made without departing from the spirit and scope of the present invention. Accordingly, the present invention should not be interpreted as being limited to the description of the embodiments below.

Note that in the structures of the invention described below, the same portions or portions having similar functions are denoted by the same reference numerals in different drawings, and description of such portions is not repeated. Further, the same hatching pattern is applied to portions having similar functions, and the portions are not denoted by reference numerals in some cases.

Note that in each drawing described in this specification, the size, the layer thickness, or the region of each component is exaggerated for clarity in some cases. Therefore, embodiments of the present invention are not limited to such scales.

Note that in this specification and the like, ordinal numbers such as “first”, “second”, and the like are used in order to avoid confusion among components and do not limit the number.

### Embodiment 1

In this embodiment, an electronic device and a driving method thereof according to one embodiment of the present invention will be described.

One embodiment of the present invention is a driving method of an electronic device which includes a display portion provided on a first surface of a housing and a position detection sensor provided on the same first surface.

The display portion is provided with a first display element and a second display element. The first display element is configured to reflect visible light, and the second display element is configured to emit visible light. The display portion is configured to display an image using one or both of first light reflected by the first display element and second light emitted by the second display element.

In this embodiment, a reflective liquid crystal element is used as the first display element, and a light-emitting element is used as the second display element. In the case where the electronic device is used under bright external light, displaying an image by the first display element enables driving with low power consumption. Furthermore, displaying an image by the second display element under weak external light enables a reduction in power consumption and an increase in display quality.

The viewing angle dependence is higher when an image is displayed by the first display element than when an image is displayed by the second display element. Specifically, the luminance of an image seen from an oblique direction of the display portion decreases and the chromaticity thereof changes from those of the image seen from the front of the display portion, which occurs more significant in the case where an image is displayed by the first display element than the case where an image is displayed by the second display element.

In the electronic device of one embodiment of the present invention, an image can be displayed using both the first display element and the second display element, and the amount of the second light (i.e., the luminance of the image displayed by the second display element) is adjusted in accordance with the angle from which the display of the display portion is viewed by the user; accordingly, the viewing angle dependence can be reduced and the display quality can be increased.

The angle from which the display of the display portion is viewed by the user is determined on the basis of the data obtained by the position detection sensor. Specifically, the position of an object (e.g., a part of the user, specifically, the head or both eyes) is specified by the position detection sensor, and the inclination of the direction in which the object exists with respect to the front direction of the position detection sensor, which is the same as the front direction of the display portion, is calculated.

Note that in the case where the first display element is regarded as a secondary light source, the luminance of the image displayed by the first display element depends on the brightness of external light. Therefore, it is preferable that the luminance of the image displayed by the second display element be adjusted on the basis of the illuminance of external light as well as the angle from which the display portion is viewed by the user. This driving method can be implemented when the electronic device of one embodiment of the present invention includes an illuminance sensor on the first surface of the housing.

More specific examples of the electronic device and the driving method thereof according to one embodiment of the present invention are described below with reference to the drawings.

### [Structure Example 1 of Electronic Device]

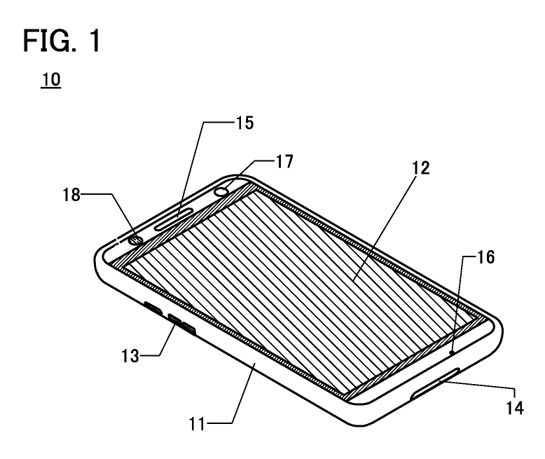

FIG. 1 is a perspective view illustrating an example of an electronic device 10 of one embodiment of the present invention. The electronic device 10 includes a housing 11, a display portion 12, and a position detection sensor 18. The display portion 12 and the position detection sensor 18 are provided on a first surface of the housing 11.

The display portion 12 is configured to display an image using one or both of first light reflected by a first display element and second light emitted by a second display element. Furthermore, the display portion 12 is configured to express gray scales by individually controlling the amount of the first light reflected by the first display element and the amount of the second light emitted by the second display element.

The display portion 12 preferably includes a first pixel that expresses gray scales by controlling the amount of light reflected by the first display element and a second pixel that expresses gray scales by controlling the amount of light emitted by the second display element. For example, a plurality of such first pixels and a plurality of such second pixels are arranged in a matrix to form the display portion 12.

The first pixels and the second pixels are preferably arranged at the same intervals in the display region. Here, the first pixel and the second pixel adjacent to each other can be collectively referred to as a pixel unit.

Furthermore, the first pixels and the second pixels are preferably mixed in the display region of the display portion 12. In that case, an image displayed by the plurality of first pixels, an image displayed by the plurality of second pixels, and an image displayed by both the plurality of first pixels and the plurality of second pixels can be displayed in the same display region, as described later.

As the first display element included in the first pixel, an element that performs display by reflecting external light can be used. Such an element does not include a light source and thus power consumption in display can be significantly low. Furthermore, in the case where the electronic device is used in an environment where the illuminance of external light is high, e.g., the outdoors under a clear sky, an image can be displayed with high luminance in accordance with the illuminance, so that high visibility display can be achieved.

As the first display element, a reflective liquid crystal element can be typically used. Alternatively, as the first display element, an element using a microcapsule method, an electrophoretic method, an electrowetting method, an Electronic Liquid

Powder (registered trademark) method, or the like as well as Micro Electro Mechanical Systems (MEMS) shutter element or an optical interference type MEMS element can be used.

As the second display element included in the second pixel, an element including a light source and performing display using light from the light source can be used. Specifically, it is preferable to use an electroluminescent element in which light can be extracted from a light-emitting substance by application of an electric field. Since the luminance and chromaticity of light emitted by such a pixel are not affected by external light, an image with high color reproducibility (a wide color gamut) and a high contrast, i.e., a clear image can be displayed.

As the second display element, a self-luminous light-emitting element such as an organic light-emitting diode (OLED), a light-emitting diode (LED), and a quantum-dot light-emitting diode (QLED) can be used. Alternatively, a combination of a backlight that serves as a light source and a transmissive liquid crystal element that controls the amount of light from the backlight transmitted therethrough may be used as the display element included in the second pixel. Alternatively, the display element included in the second pixel may have a structure including a light-emitting diode or a structure that uses a semiconductor laser.

In this embodiment, a reflective liquid crystal element is used as the first display element and a light-emitting element is used as the second display element.

The first pixel can include, for example, a subpixel exhibiting light of white (W), or subpixels exhibiting light of three colors of red (R), green (G), and blue (B). Similarly, the second pixel can include, for example, a subpixel exhibiting light of white (W), or subpixels exhibiting light of three colors of red (R), green (G), and blue (B). Note that the first pixel and the second pixel may each include four or more subpixels. As the number of kinds of subpixels is increased, power consumption can be reduced and color reproducibility can be improved.

In the display portion 12, switching between a first display mode in which an image is displayed by the first pixels, a second display mode in which an image is displayed by the second pixels, and a third display mode in which an image is displayed by the first pixels and the second pixels can be performed.

In the first display mode, an image is displayed using light reflected by the first display element. The first display mode is a driving mode with extremely low power consumption because a light source is unnecessary, and is effective in the case where, for example, external light has sufficiently high illuminance and is white light or light near white light. The first display mode is a display mode suitable for displaying text information of a book or a document, for example. The first display mode can offer eye-friendly display owing to the use of reflected light and thus has an effect of being unlikely to cause eyestrain.

In the second display mode, an image is displayed using light emitted by the second display element. Thus, an extremely clear image (with a high contrast and high color reproducibility) can be displayed regardless of the illuminance and chromaticity of external light. For example, the second display mode is effective in the case where the illuminance of external light is extremely low, such as during the nighttime or in a dark room. When a bright image is displayed under weak external light, a user may feel that the image is too bright. To prevent this, an image with reduced luminance is preferably displayed in the second display mode. In that case, reducing the luminance can achieve low power consumption as well as preventing brightness. The second display mode is a mode suitable for displaying a vivid image and a smooth moving image, for example.

In the third display mode, an image is displayed using both light reflected by the first display element and light emitted by the second display element. Specifically, the electronic device is driven so that light emitted by the first pixel and light emitted by the second pixel adjacent to the first pixel are mixed to express one color. A clearer image than that in the first display mode can be displayed and power consumption can be lower than that in the second display mode. For example, the third display mode is effective when the illuminance of external light is relatively low, such as under indoor illumination or in the morning or evening, or when the external light does not represent a white chromaticity.

In the case where an image is displayed in the third display mode, the electronic device 10 can determine the angle from which the display of the display portion 12 is viewed by the user with the use of the position detection sensor 18, and adjust the luminance of the image displayed by the second display element (the amount of the second light) in accordance with the angle. Thus, in the electronic device 10, the third display mode can have lower viewing angle dependence than the first display mode, leading to higher display quality. Furthermore, under high illuminance of external light, because light emitted by the second display element is supplementary light (the luminance of light reflected by the first display element is higher than that of light emitted by the second display element) in the third display mode, the viewing angle dependence can be reduced and power consumption can be reduced.

The amount of the second light can be adjusted by the adjustment of the data amplitude (the maximum grayscale value), for example. In the case where the display of the display portion 12 is viewed obliquely by a user in the third display mode, the data amplitude is set larger than that in the case where it is viewed from the front to increase the luminance of light emitted by the second display element. A specific method for adjusting the data amplitude is described in Example.

As the position detection sensor 18, an element that senses visible light such as a CCD sensor or a CMOS sensor can be used (see FIG. 1).

### [Other Structures of Electronic Device]

The electronic device 10 includes an operation button 13, an external connection port 14, a speaker 15, a microphone 16, a camera 17, and the like. P In the electronic device 10, the display portion 12 is provided with a touch sensor. Operations such as making a call and inputting a letter can be performed by touch on the display portion 12 with a finger, a stylus, or the like.

With the operation button 13, power ON or OFF can be switched. In addition, types of images displayed on the display portion 12 can be switched; for example, switching images from a mail creation screen to a main menu screen can be performed.

When a detection device such as a gyroscope sensor or an acceleration sensor is provided inside the electronic device 10, the direction of display on the screen of the display portion 12 can be automatically changed by determining the orientation of the electronic device 10 (whether the electronic device 10 is placed horizontally or vertically). Furthermore, the direction of display on the screen can be changed by touch on the display portion 12, operation with the operation button 13, sound input using the microphone 16, or the like.

The electronic device 10 has one or more of a telephone function, a notebook function, an information browsing function, and the like, for example. Specifically, the electronic device 10 can be used as a smartphone. The electronic device 10 is capable of executing a variety of applications such as mobile phone calls, e-mailing, viewing and editing texts, music reproduction, moving image reproduction, Internet communication, and computer games, for example.

Note that the camera 17 may have a function of the position detection sensor 18. In this case, the electronic device 10 is not necessarily provided with the position detection sensor 18.

### [Method for Detecting Positional Data]

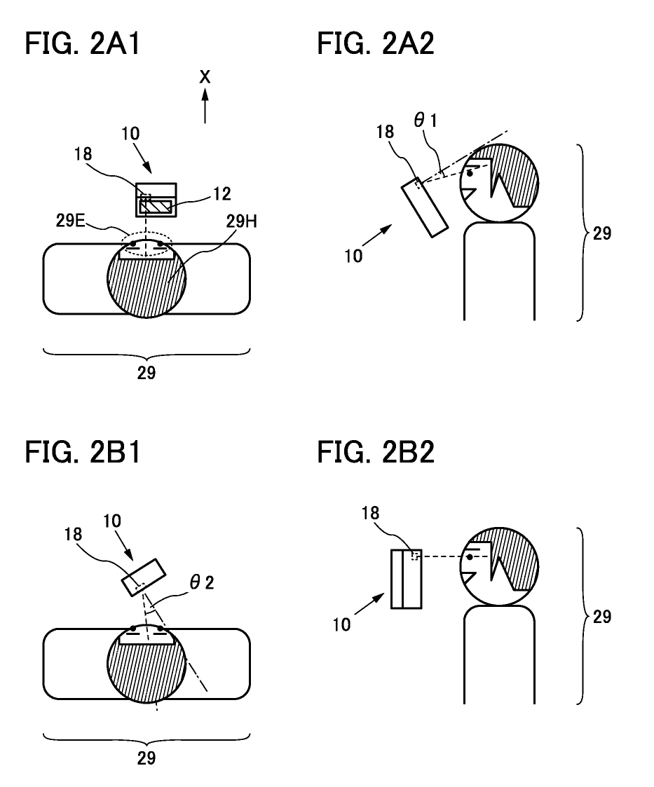

FIGS. 2A1, 2A2, 2B1, and 2B2 are schematic views illustrating states in which a user 29 uses the electronic device 10. An angle θ from which the display portion is viewed by the user is described with reference to FIGS. 2A1, 2A2, 2B1, and 2B2. Note that a hand of the user holding the electronic device is not illustrated in FIGS. 2A1, 2A2, 2B1, and 2B2.

FIGS. 2A1 and 2B1 are top views illustrating states in which the user 29 holds the electronic device 10 at different angles. FIGS. 2A2 and 2B2 are side views corresponding to FIGS. 2A1 and 2B1, respectively.

In FIGS. 2A1 and 2A2, the user 29 holds the electronic device 10 so that the first surface (the surface provided with the display portion 12 and the position detection sensor 18) faces obliquely upward. In FIG. 2A2, a dashed-dotted line shows the front direction of the position detection sensor 18, and a broken line shows the direction of a part of the user 29 detected by the position detection sensor 18 from the position detection sensor 18 (also referred to as a detection direction below). The angle from which the display portion is viewed by the user 29 is an angle θ1 in FIG. 2A2. In the top view of FIG. 2A1, the front direction of the position detection sensor 18 and the detection direction are the same, so that only the broken line indicating the detection direction is shown in FIG. 2A1.

Furthermore, in FIGS. 2B1 and 2B2, the user 29 holds the electronic device 10 so that the first surface (the surface provided with the display portion 12 and the position detection sensor 18) faces to the right of the user 29. In FIG. 2B1, a dashed-dotted line shows the front direction of the position detection sensor 18, and a broken line shows the detection direction. The angle from which the display portion is viewed by the user 29 is an angle θ2 in FIG. 2B1. In the side view of FIG. 2B2, the front direction of the position detection sensor 18 and the detection direction are the same, so that only the broken line indicating the detection direction is shown in FIG. 2B2.

A part of the user 29 detected by the position detection sensor 18 can be both eyes 29E or a head 29H, for example (see FIG. 2A1). In the examples in FIGS. 2A1, 2A2, 2B1, and 2B2, the position detection sensor 18 detects the both eyes 29E of the user 29.

### [Driving Method 1 of Electronic Device]

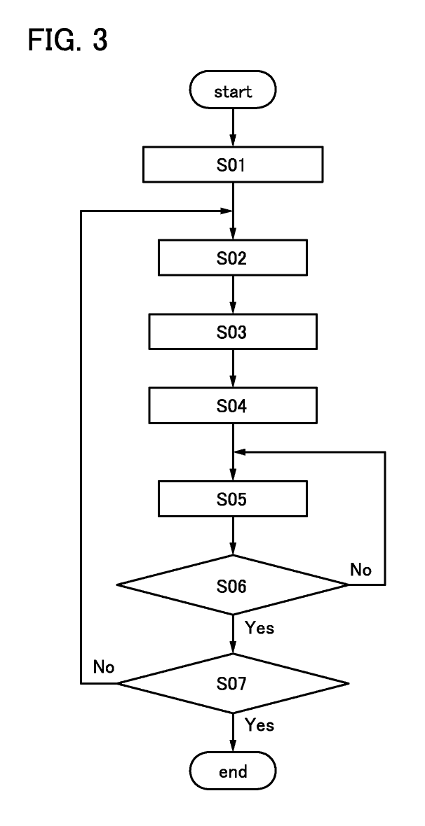

A method for driving the electronic device 10 in which the angle θ detected by the position detection sensor 18 is reflected in display in the third display mode is described below with reference to FIG. 3. The driving method involves the following seven steps.

First, the third display mode is set in the electronic device 10 (see Step S01 in FIG. 3).

Then, the position detection sensor 18 detects positional data of the user 29 (see Step S02 in FIG. 3). The angle θ from which the display portion is viewed by the user 29, which has been explained using FIGS. 2A1, 2A2, 2B1, and 2B2, is determined on the basis of the positional data.

Next, a data amplitude Vr is determined on the basis of the angle θ (see Step S03 in FIG. 3). The data amplitude Vr is preferably determined on the color basis. For example, in the case where the display portion 12 includes subpixels exhibiting light of three colors of RGB, a data amplitude VrR for red, a data amplitude VrG for green, and a data amplitude VrB for blue are determined in Step S03.

Moreover, the value of the data amplitude Vr corresponding to the angle θ is preferably determined in advance. For example, first, the luminance and chromaticity are measured at a display angle α in the first display mode to calculate viewing angle dependence in the first display mode. Note that the display angle α is an inclination angle with respect to the front direction of the display portion 12 and is, for example, greater than or equal to −75° and less than or equal to 75°. Then, the luminance and chromaticity at the display angle α in the third display mode are measured with varying data amplitude Vr to obtain the data amplitude Vr at which the viewing angle dependence in the third display mode is lower than that in the first display mode. By this measurement, a function of the data amplitude Vr using the angle α as a variable can be obtained.

Then, the data amplitude Vr obtained in Step S03 is reflected in display in the third display mode (see Step S04 in FIG. 3).

Next, standby time is counted. The counting of the standby time continues until predesignated time has passed (see Step S05 and Step S06 in FIG. 3). Here, the update frequency of the data amplitude Vr can be determined in accordance with the designated time. In the case where the update frequency is low, flicker of display occurs when the user moves to change the angle θ; accordingly, the update frequency is preferably as high as possible. For example, the update frequency is preferably higher than or equal to 4 Hz and lower than or equal to 30 Hz. Here, 1 Hz represents an update of the data amplitude Vr per second.

Then, the display mode is confirmed. If the display mode is not changed from the third display mode, the detection of positional data is performed again. While in the case where the display mode is changed from the third display mode by operation of the electronic device 10 by the user 29, the update of the data amplitude Vr is stopped (see Step S07 in FIG. 3).

Through Steps S01 to S07, the electronic device 10 can perform display on the display portion 12 with the viewing angle dependence reduced even when the angle from which the display portion is viewed by the user 29 is changed.

### [Structure Example 2 of Electronic Device]

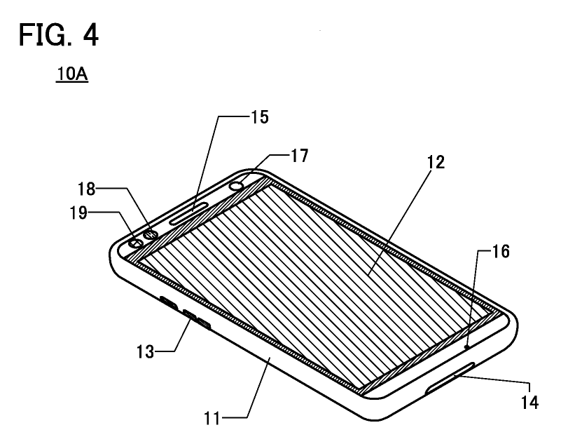

FIG. 4 is a perspective view illustrating an example of an electronic device 10A of one embodiment of the present invention which is partly different from the above-described electronic device 10. Since the above description can be referred to for the components common to those in the electronic device 10, components different from those of the electronic device 10 are described below.

The electronic device 10A includes the housing 11, the display portion 12, the position detection sensor 18, and an illuminance sensor 19. The display portion 12, the position detection sensor 18, and the illuminance sensor 19 are provided on the first surface of the housing 11. The electronic device 10A is different from the above-described electronic device 10 in including the illuminance sensor 19.

The illuminance sensor 19 is configured to measure the illuminance of external light. The electronic device 10A can adjust the luminance of an image displayed by the second display element (the amount of the second light) in accordance with the angle from which the display portion is viewed by the user and the illuminance of external light, in the case where the display portion 12 performs display in the third display mode.

In the case where the first display element is regarded as a secondary light source, the luminance of an image displayed by the first display element depends on the brightness of external light. Thus, in an environment where the brightness of external light changes (e.g., in outdoor walking), it is preferable to consider the illuminance of external light as well in determining the data amplitude Vr in the third display mode. Since the electronic device 10A includes the illuminance sensor 19, even in an environment where the brightness of external light changes, the viewing angle dependence in the third display mode can be reduced, leading to higher display quality.

### [Driving Method 2 of Electronic Device]

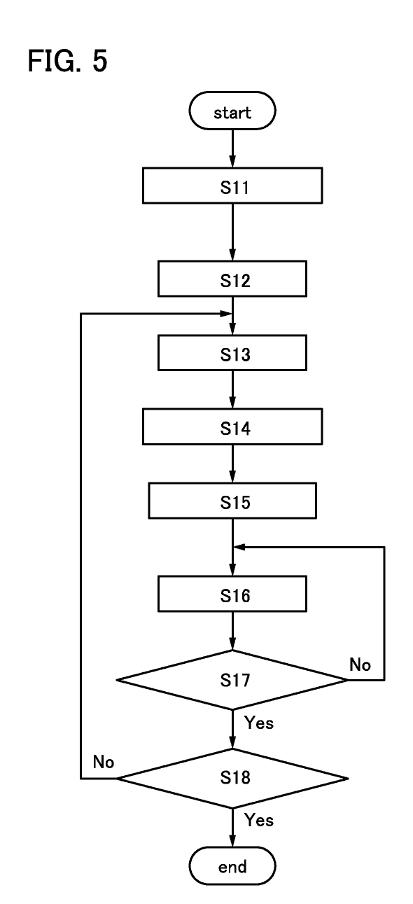

A method for driving the electronic device 10A in which an illuminance I detected by the illuminance sensor 19 and the angle θ detected by the position detection sensor 18 are reflected in display in the third display mode is described below with reference to FIG. 5. The driving method involves the following eight steps.

First, the third display mode is set in the electronic device 10A (see Step S11 in FIG. 5).

Next, the illuminance sensor 19 determines the illuminance I in an environment where the electronic device 10A is used (see Step S12 in FIG. 5).

Then, the position detection sensor 18 detects positional data of the user 29 (see Step S13 in FIG. 5). The angle θ from which the display portion is viewed by the user, which has been explained using FIGS. 2A1, 2A2, 2B1, and 2B2, is determined on the basis of the positional data.

Next, a data amplitude Vr is determined on the basis of the illuminance I and the angle θ (see Step S14 in FIG. 5). The data amplitude Vr is preferably determined on the color basis. For example, in the case where the display portion 12 includes subpixels exhibiting light of three colors of RGB, a data amplitude VrR for red, a data amplitude VrG for green, and a data amplitude VrB for blue are determined in Step S13.

Moreover, the value of the data amplitude Vr corresponding to the illuminance I and the angle θ is preferably determined in advance. For example, first, the luminance and chromaticity are measured at an illuminance A and a display angle α in the first display mode to calculate viewing angle dependence in the first display mode. Note that the illuminance A is, for example, greater than or equal to 2000 lux and less than or equal to 30000 lux. In addition, the display angle α is an inclination angle with respect to the front direction of the display portion 12 and is, for example, greater than or equal to −75° and less than or equal to 75°. Then, the luminance and chromaticity at the illuminance A and the display angle α in the third display mode are measured with varying data amplitude Vr to obtain the data amplitude Vr at which the viewing angle dependence in the third display mode is lower than that in the first display mode. By this measurement, a function of the data amplitude Vr using the illuminance A and the angle α as variables can be obtained.

Then, the data amplitude Vr obtained in Step S14 is reflected in display in the third display mode (see Step S15 in FIG. 5).

Next, standby time is counted. The counting of the standby time continues until predesignated time has passed (see Step S16 and Step S17 in FIG. 5). Here, the update frequency of the data amplitude Vr can be determined in accordance with the designated time. In the case where the update frequency is low, flicker of display occurs when the electronic device is used in an environment where the illuminance I varies or when the user moves to change the angle θ; accordingly, the update frequency is preferably as high as possible. For example, the update frequency is preferably higher than or equal to 4 Hz and lower than or equal to 30 Hz. Here, 1 Hz represents an update of the data amplitude Vr per second.

Then, the display mode is confirmed. If the display mode is not changed from the third display mode, the detection of positional data is performed again. While in the case where the display mode is changed from the third display mode by operation of the electronic device 10A by the user 29, the update of the data amplitude Vr is stopped (see Step S18 in FIG. 5).

Through Steps S11 to S18, the electronic device 10A can perform display on the display portion 12 with the viewing angle dependence reduced even when the illuminance in the usage environment and/or the angle from which the display portion is viewed by the user 29 is/are changed.

At least part of this embodiment can be implemented in combination with any of the other embodiments described in this specification as appropriate.

### Embodiment 2

An example of a display panel which can be used for a display portion or the like in the electronic device of one embodiment of the present invention is described below. The display panel described below as an example includes both a reflective liquid crystal element and a light-emitting element and can display an image using either or both of the liquid crystal element and the light-emitting element.

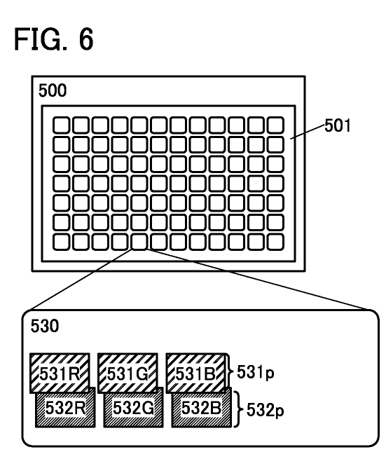

FIG. 6 is a block diagram of a display device 500. The display device 500 includes a display portion 501.

The display portion 501 includes a plurality of pixel units 530 arranged in a matrix. The pixel units 530 each include a first pixel 531p and a second pixel 532p.

FIG. 6 shows an example where the first pixel 531p and the second pixel 532p each include display elements corresponding to three colors of red (R), green (G), and blue (B).

The display elements included in the first pixel 531p are each a display element that utilizes reflection of external light. The first pixel 531p includes a first display element 531R corresponding to red (R), a first display element 531G corresponding to green (G), and a first display element 531B corresponding to blue (B).

The display elements included in the second pixel 532p are each a light-emitting element. The second pixel 532p includes a second display element 532R corresponding to red (R), a second display element 532G corresponding to green (G), and a second display element 532B corresponding to blue (B).

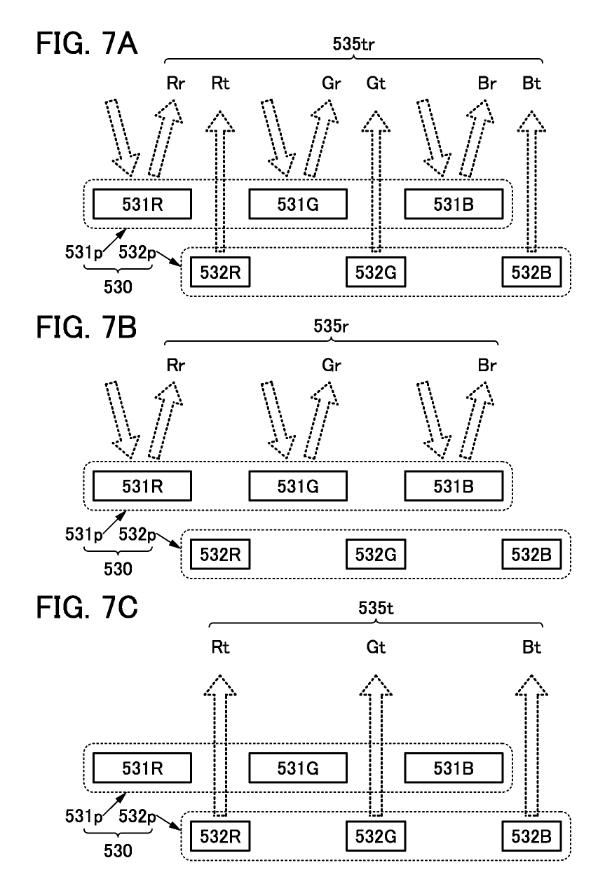

FIGS. 7A to 7C are schematic views illustrating a structure example of the pixel unit 530.

The first pixel 531p includes the first display element 531R, the first display element 531G, and the first display element 531B. The first display element 531R reflects external light and emits red light Rr to the display surface side. Similarly, the first display element 531G and the first display element 531B emit green light Gr and blue light Br, respectively, to the display surface side.

The second pixel 532p includes the second display element 532R, the second display element 532G, and the second display element 532B. The second display element 532R emits red light Rt to the display surface side. Similarly, the second display element 532G and the second display element 532B emit green light Gt and blue light Bt, respectively, to the display surface side.

FIG. 7A corresponds to a display mode (third display mode) in which both the first pixel 531p and the second pixel 532p are driven. The pixel unit 530 can emit light 535tr of a predetermined color to the display surface side using the reflected light (the light Rr, the light Gr, and the light Br) and the transmitted light (the light Rt, the light Gt, and the light Bt).

FIG. 7B corresponds to a display mode (first display mode) using reflected light in which only the first pixel 531p is driven. For example, when the intensity of external light is high enough, the pixel unit 530 can emit light 535r to the display surface side using only the light from the first pixel 531p (the light Rr, the light Gr, and the light Br), without driving the second pixel 532p. Thus, driving with extremely low power consumption can be performed.

FIG. 7C corresponds to a display mode (second display mode) using generated light (transmitted light) in which only the second pixel 532p is driven. For example, when the intensity of external light is extremely low, the pixel unit 530 can emit light 535t to the display surface side using only the light from the second pixel 532p (the light Rt, the light Gt, and the light Bt), without driving the first pixel 531p. Thus, a vivid image can be displayed. Furthermore, by lowering the luminance in a dark environment, a user can be prevented from feeling glare and power consumption can be reduced.

The color and number of display elements included in the first pixel 531p and the second pixel 532p are not limited.

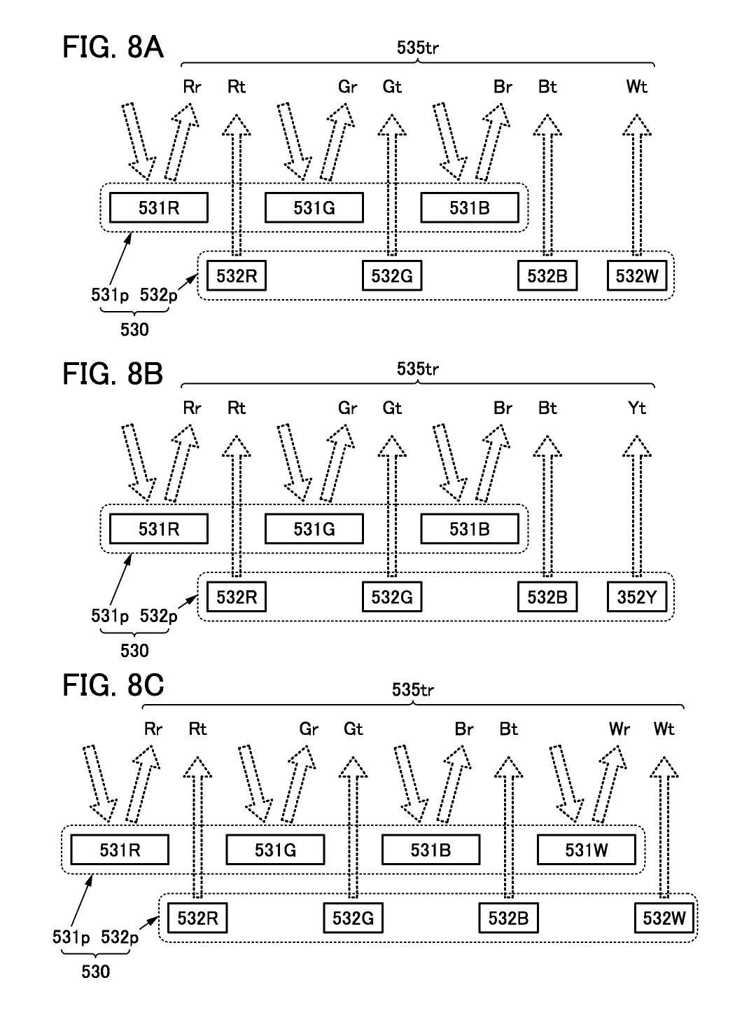

FIGS. 8A to 8C each illustrate a structure example of the pixel unit 530. Although FIGS. 8A to 8C are schematic views corresponding to the display mode (third display mode) in which both the first pixel 531p and the second pixel 532p are driven, display can also be performed in the mode (first display mode or second display mode) in which only the first pixel 531p or the second pixel 532p is driven, like the above-described structure example.

The second pixel 532p illustrated in FIGS. 8A and 8C includes a second display element 532W emitting white (W) light in addition to the second display element 532R, the second display element 532G, and the second display element 532B.

The second pixel 532p illustrated in FIG. 8B includes a second display element 532Y emitting yellow (Y) light in addition to the second display element 532R, the second display element 532G, and the second display element 532B.

Power consumption in the display mode using the second pixel 532p (second display mode and third display mode) can be lower in the structures illustrated in FIGS. 8A to 8C than in the structure not including the second display element 532W or the second display element 532Y.

The first pixel 531p illustrated in FIG. 8C includes a first display element 531W emitting white (W) light in addition to the first display element 531R, the first display element 531G, and the first display element 531B.

Power consumption in the display mode using the first pixel 531p (first display mode and third display mode) can be lower in the structure illustrated in FIG. 8C than in the structure illustrated in FIG. 7A.

At least part of this embodiment can be implemented in combination with any of the other embodiments described in this specification as appropriate.

### Embodiment 3

In this embodiment, more specific examples of the display device described in Embodiment 2 will be described with reference to drawings.

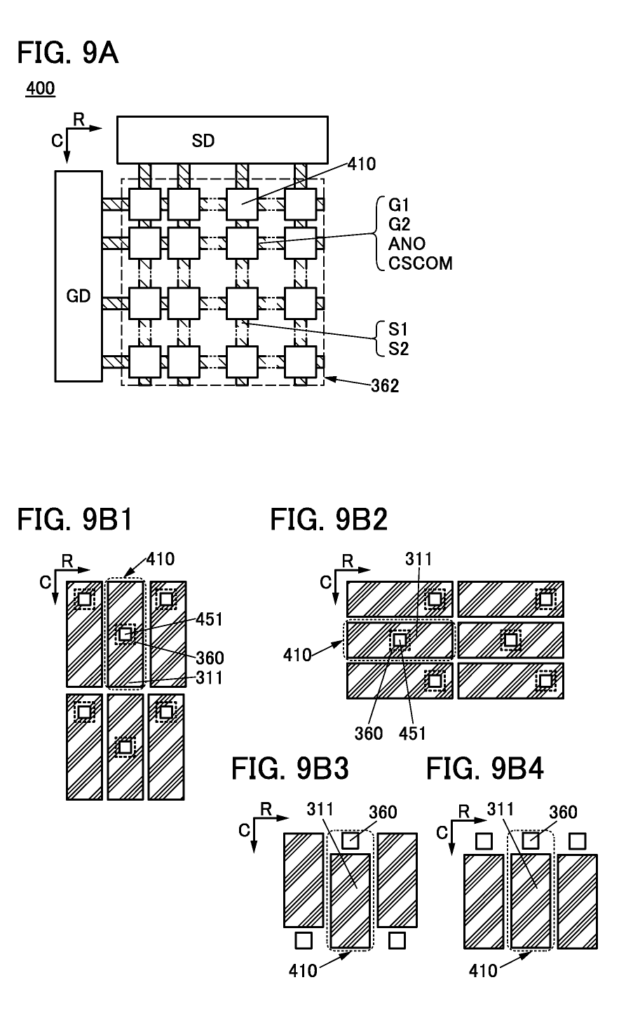

FIG. 9A is a block diagram of a display device 400. The display device 400 includes a display portion 362, a circuit GD, and a circuit SD. The display portion 362 includes a plurality of pixels 410 arranged in a matrix.

The display device 400 includes a plurality of wirings G1, a plurality of wirings G2, a plurality of wirings ANO, a plurality of wirings CSCOM, a plurality of wirings S1, and a plurality of wirings S2. The plurality of wirings G1, the plurality of wirings G2, the plurality of wirings ANO, and the plurality of wirings CSCOM are each electrically connected to the circuit GD and the plurality of pixels 410 arranged in a direction indicated by an arrow R. The plurality of wirings 51 and the plurality of wirings S2 are each electrically connected to the circuit SD and the plurality of pixels 410 arranged in a direction indicated by an arrow C.

Although the structure including one circuit GD and one circuit SD is illustrated here for simplicity, the circuit GD and the circuit SD for driving liquid crystal elements and the circuit GD and the circuit SD for driving light-emitting elements may be provided separately.

The pixels 410 each include a reflective liquid crystal element and a light-emitting element.

FIGS. 9B1, 9B2, 9B3, and 9B4 illustrate structure examples of an electrode 311 included in the pixel 410. The electrode 311 serves as a reflective electrode of the liquid crystal element. An opening 451 is provided in the electrode 311 in FIGS. 9B1 and 9B2.

In FIGS. 9B1 and 9B2, a light-emitting element 360 positioned in a region overlapping with the electrode 311 is indicated by a broken line. The light-emitting element 360 overlaps with the opening 451 included in the electrode 311. Thus, light from the light-emitting element 360 is emitted to the display surface side through the opening 451.

In FIG. 9B1, the pixels 410 which are adjacent in the direction indicated by the arrow R are pixels emitting light of different colors. As illustrated in FIG. 9B1, the openings 451 are preferably provided in different positions in the electrodes 311 so as not to be aligned in two adjacent pixels provided in the direction indicated by the arrow R. This allows two light-emitting elements 360 to be apart from each other, thereby preventing light emitted from the light-emitting element 360 from entering a coloring layer in the adjacent pixel 410 (such a phenomenon is referred to as crosstalk). Furthermore, since two adjacent light-emitting elements 360 can be arranged apart from each other, a high-resolution display device is achieved even when EL layers of the light-emitting elements 360 are separately formed with a shadow mask or the like.

In FIG. 9B2, the pixels 410 which are adjacent in a direction indicated by the arrow C are pixels emitting light of different colors. Also in FIG. 9B2, the openings 451 are preferably provided in different positions in the electrodes 311 so as not to be aligned in two adjacent pixels provided in the direction indicated by the arrow C.

As the ratio of the total area of the opening 451 to the total area except for the opening is smaller, display performed using the liquid crystal element can be brighter. Furthermore, as the ratio of the total area of the opening 451 to the total area except for the opening is larger, display performed using the light-emitting element 360 can be brighter.

The opening 451 may have a polygonal shape, a quadrangular shape, an elliptical shape, a circular shape, a cross-like shape, a stripe shape, a slit-like shape, or a checkered pattern, for example. The opening 451 may be provided close to the adjacent pixel. Preferably, the opening 451 is provided close to another pixel emitting light of the same color, in which case crosstalk can be suppressed.

As illustrated in FIGS. 9B3 and 9B4, a light-emitting region of the light-emitting element 360 may be positioned in a region where the electrode 311 is not provided, in which case light emitted from the light-emitting element 360 is emitted to the display surface side.

In FIG. 9B3, the light-emitting elements 360 are not aligned in two adjacent pixels 410 provided in the direction indicated by the arrow R. In FIG. 9B4, the light-emitting elements 360 are aligned in two adjacent pixels 410 provided in the direction indicated by the arrow R.

The structure illustrated in FIG. 9B3 can, as mentioned above, prevent crosstalk and increase the resolution because the light-emitting elements 360 included in two adjacent pixels 410 can be apart from each other. The structure illustrated in FIG. 9B4 can prevent light emitted from the light-emitting element 360 from being blocked by the electrode 311 because the electrode 311 is not positioned along a side of the light-emitting element 360 which is parallel to the direction indicated by the arrow C. Thus, high viewing angle characteristics can be achieved.

As the circuit GD, any of a variety of sequential circuits such as a shift register can be used. In the circuit GD, a transistor, a capacitor, and the like can be used. A transistor included in the circuit GD can be formed in the same steps as the transistors included in the pixels 410.

The circuit SD is electrically connected to the wirings 51. For example, an integrated circuit can be used as the circuit SD. Specifically, an integrated circuit formed on a silicon substrate can be used as the circuit SD.

For example, a chip on glass (COG) method, a chip on film (COF) method, or the like can be used to mount the circuit SD on a pad electrically connected to the pixels 410. Specifically, an anisotropic conductive film can be used to mount an integrated circuit on the pad.

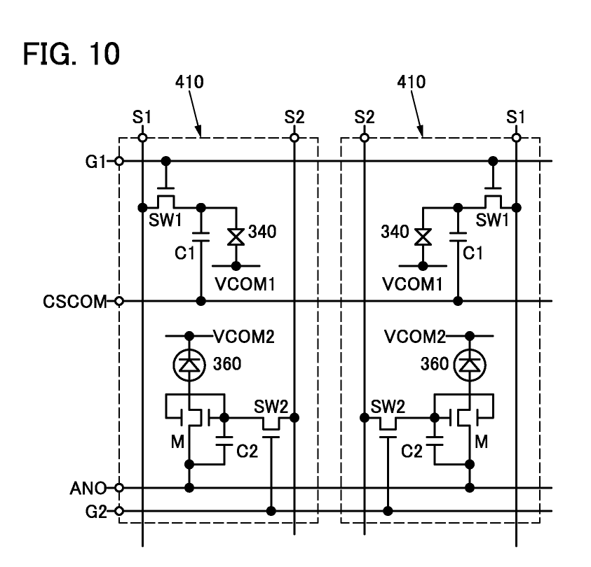

FIG. 10 is an example of a circuit diagram of the pixels 410. FIG. 10 shows two adjacent pixels 410.

The pixels 410 each include a switch SW1, a capacitor C1, a liquid crystal element 340, a switch SW2, a transistor M, a capacitor C2, the light-emitting element 360, and the like. The pixel 410 is electrically connected to the wiring G1, the wiring G2, the wiring ANO, the wiring CSCOM, the wiring S1, and the wiring S2. FIG. 10 illustrates a wiring VCOM1 electrically connected to the liquid crystal element 340 and a wiring VCOM2 electrically connected to the light-emitting element 360.

FIG. 10 illustrates an example in which a transistor is used as each of the switches SW1 and SW2.

A gate of the switch SW1 is connected to the wiring G1. One of a source and a drain of the switch SW1 is connected to the wiring S1, and the other is connected to one electrode of the capacitor C1 and one electrode of the liquid crystal element 340. The other electrode of the capacitor C1 is connected to the wiring CSCOM. The other electrode of the liquid crystal element 340 is connected to the wiring VCOM1.

A gate of the switch SW2 is connected to the wiring G2. One of a source and a drain of the switch SW2 is connected to the wiring S2, and the other is connected to one electrode of the capacitor C2 and gates of the transistor M. The other electrode of the capacitor C2 is connected to one of a source and a drain of the transistor M and the wiring ANO. The other of the source and the drain of the transistor M is connected to one electrode of the light-emitting element 360. Furthermore, the other electrode of the light-emitting element 360 is connected to the wiring VCOM2.

FIG. 10 illustrates an example where the transistor M includes two gates between which a semiconductor layer is provided and which are connected to each other. This structure can increase the amount of current flowing through the transistor M.

The wiring G1 can be supplied with a signal for changing the on/off state of the switch SW1. A predetermined potential can be supplied to the wiring VCOM1. The wiring S1 can be supplied with a signal for changing the orientation of liquid crystals of the liquid crystal element 340. A predetermined potential can be supplied to the wiring CSCOM.

The wiring G2 can be supplied with a signal for changing the on/off state of the switch SW2. The wiring VCOM2 and the wiring ANO can be supplied with potentials having a difference large enough to make the light-emitting element 360 emit light. The wiring S2 can be supplied with a signal for changing the conduction state of the transistor M.

In the pixel 410 of FIG. 10, for example, an image can be displayed in the reflective mode by driving the pixel with the signals supplied to the wiring G1 and the wiring S1 and utilizing the optical modulation of the liquid crystal element 340. In the case where an image is displayed in the transmissive mode, the pixel is driven with the signals supplied to the wiring G2 and the wiring S2 and the light-emitting element 360 emits light. In the case where both display modes are performed at the same time, the pixel can be driven with the signals supplied to the wiring G1, the wiring G2, the wiring 51, and the wiring S2.

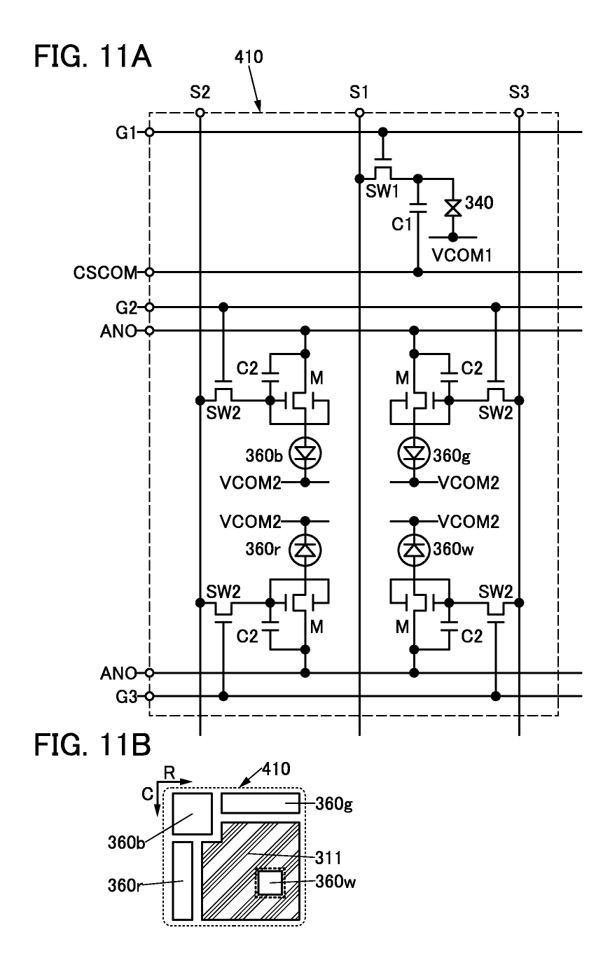

Although FIG. 10 illustrates an example in which one liquid crystal element 340 and one light-emitting element 360 are provided in one pixel 410, one embodiment of the present invention is not limited thereto. FIG. 11A illustrates an example in which one liquid crystal element 340 and four light-emitting elements 360 (light-emitting elements 360r, 360g, 360b, and 360w) are provided in one pixel 410. The pixel 410 illustrated in FIG. 11A differs from that in FIG. 10 in being capable of performing full-color display with the use of the light-emitting elements by one pixel.

In FIG. 11A, in addition to the wirings in FIG. 10, a wiring G3 and a wiring S3 are connected to the pixel 410.

In the example in FIG. 11A, light-emitting elements emitting red light (R), green light (B), blue light (B), and white light (W) can be used as the four light-emitting elements 360r, 360g, 360b, and 360w, for example. Furthermore, as the liquid crystal element 340, a reflective liquid crystal element emitting white light can be used. Thus, in the case of performing display in the reflective mode, white display with high reflectivity can be performed. In the case of performing display in the transmissive mode, images can be displayed with a higher color rendering property at low power consumption.

FIG. 11B illustrates a structure example of the pixel 410 corresponding to FIG. 11A. The pixel 410 includes the light-emitting element 360w overlapping with the opening included in the electrode 311 and the light-emitting element 360r, the light-emitting element 360g, and the light-emitting element 360b which are arranged in the periphery of the electrode 311. It is preferable that the light-emitting elements 360r, 360g, and 360b have almost the same light-emitting area.

At least part of this embodiment can be implemented in combination with any of the other embodiments described in this specification as appropriate.

### Embodiment 4

In this embodiment, specific structure examples of the display device described in Embodiments 2 and 3 will be described with reference to drawings.

### [Structure Example 1]

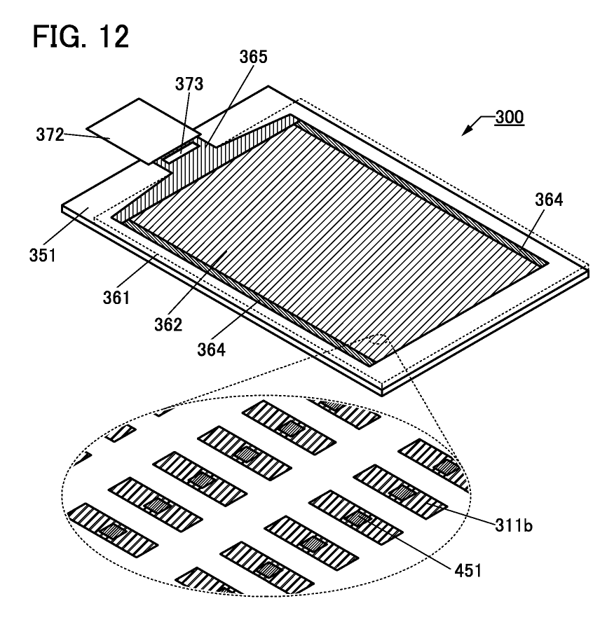

FIG. 12 is a schematic perspective view of a display device 300. In the display device 300, the substrate 351 and the substrate 361 are bonded to each other. In FIG. 12, the substrate 361 is denoted by a dashed line.

The display device 300 includes a display portion 362, a circuit 364, a wiring 365, and the like. FIG. 12 illustrates an example in which the display device 300 is provided with an integrated circuit (IC) 373 and a flexible printed circuit (FPC) 372. Thus, the structure illustrated in FIG. 12 can be regarded as a display module including the display device 300, the IC, and the FPC.

As the circuit 364, for example, a scan line driver circuit can be used.

The wiring 365 has a function of supplying a signal and power to the display portion 362 and the circuit 364. The signal and power are input to the wiring 365 from the outside through the FPC 372 or from the IC 373.

FIG. 12 illustrates an example in which the IC 373 is provided over the substrate 351 by a COG method, a COF method, or the like. An IC including a scan line driver circuit, a signal line driver circuit, or the like can be used as the IC 373, for example. Note that the display device 300 and the display module are not necessarily provided with an IC. The IC may be provided over the FPC by a COF method or the like.

FIG. 12 illustrates an enlarged view of part of the display portion 362. Electrodes 311b included in a plurality of display elements are arranged in a matrix in the display portion 362. The electrode 311b has a function of reflecting visible light, and serves as a reflective electrode of the liquid crystal element 180.

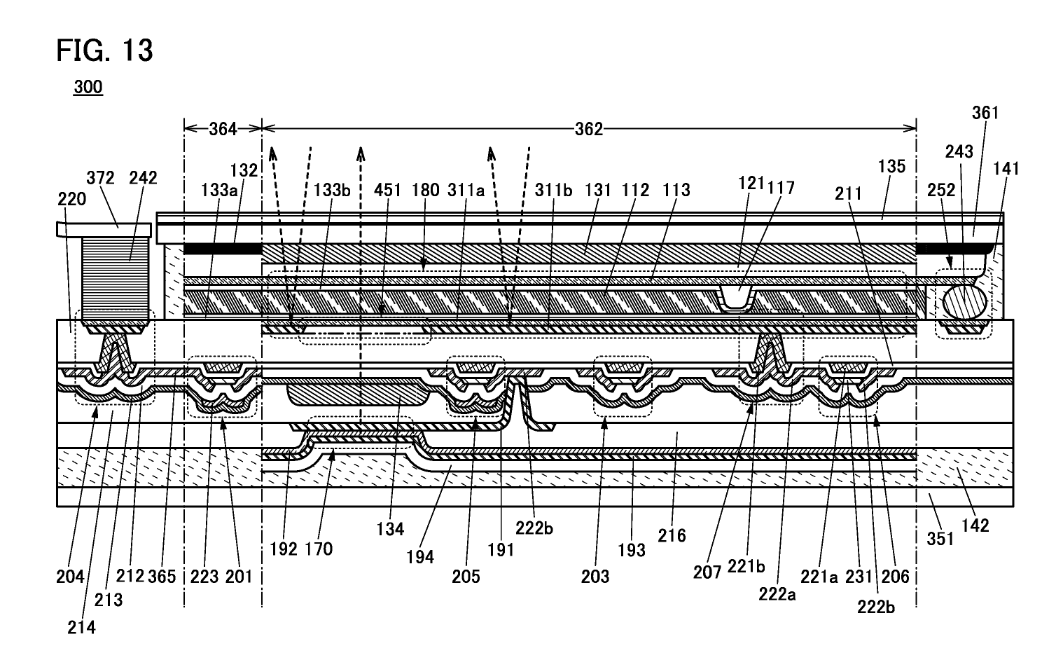

As illustrated in FIG. 12, the electrode 311b includes an opening 451. In addition, as illustrated in FIG. 13, the display portion 362 includes the light-emitting element 170 that is positioned closer to the substrate 351 than the electrode 311b. Light from the light-emitting element 170 is emitted to the substrate 361 side through the opening 451 in the electrode 311b. The area of the light-emitting region of the light-emitting element 170 may be equal to the area of the opening 451. One of the area of the light-emitting region of the light-emitting element 170 and the area of the opening 451 is preferably larger than the other because a margin for misalignment can be increased. It is particularly preferable that the area of the opening 451 be larger than the area of the light-emitting region of the light-emitting element 170. When the area of the opening 451 is small, part of light from the light-emitting element 170 is blocked by the electrode 311b and cannot be extracted to the outside, in some cases. The opening 451 with a sufficiently large area can reduce waste of light emitted from the light-emitting element 170.

FIG. 13 illustrates an example of cross-sections of part of a region including the FPC 372, part of a region including the circuit 364, and part of a region including the display portion 362 of the display device 300 illustrated in FIG. 12.

The display device 300 illustrated in FIG. 13 includes a transistor 201, a transistor 203, a transistor 205, a transistor 206, the liquid crystal element 180, the light-emitting element 170, the insulating layer 220, a coloring layer 131, a coloring layer 134, and the like, between the substrate 351 and the substrate 361. The substrate 361 and the insulating layer 220 are bonded to each other with an adhesive layer 141. The substrate 351 and the insulating layer 220 are bonded to each other with the adhesive layer 142.

The substrate 361 is provided with the coloring layer 131, a light-blocking layer 132, an insulating layer 121, the electrode 113 functioning as a common electrode of the liquid crystal element 180, the alignment film 133b, an insulating layer 117, and the like. A polarizing plate 135 is provided on an outer surface of the substrate 361. The insulating layer 121 may have a function of a planarization layer. The insulating layer 121 enables the electrode 113 to have an almost flat surface, resulting in a uniform alignment state of a liquid crystal 112. The insulating layer 117 serves as a spacer for holding a cell gap of the liquid crystal element 180. In the case where the insulating layer 117 transmits visible light, the insulating layer 117 may be positioned to overlap with a display region of the liquid crystal element 180.

The liquid crystal element 180 is a reflective liquid crystal element. The liquid crystal element 180 has a stacked-layer structure of an electrode 311a, the liquid crystal 112, and the electrode 113. The electrode 311b that reflects visible light is provided in contact with a surface of the electrode 311a on the substrate 351 side. The electrode 311b includes the opening 451. The electrode 311a and the electrode 113 transmit visible light. The alignment film 133a is provided between the liquid crystal 112 and the electrode 311a. The alignment film 133b is provided between the liquid crystal 112 and the electrode 113.

In the liquid crystal element 180, the electrode 311b has a function of reflecting visible light, and the electrode 113 has a function of transmitting visible light. Light entering from the substrate 361 side is polarized by the polarizing plate 135, transmitted through the electrode 113 and the liquid crystal 112, and reflected by the electrode 311b. Then, the light is transmitted through the liquid crystal 112 and the electrode 113 again to reach the polarizing plate 135. In this case, alignment of a liquid crystal can be controlled with a voltage that is applied between the electrode 311b and the electrode 113, and thus optical modulation of light can be controlled. In other words, the intensity of light emitted through the polarizing plate 135 can be controlled. Light excluding light in a particular wavelength region is absorbed by the coloring layer 131, and thus, emitted light is red light, for example.

As illustrated in FIG. 13, the electrode 311a that transmits visible light is preferably provided across the opening 451. Accordingly, liquid crystals in the liquid crystal 112 are aligned in a region overlapping with the opening 451 as in the other regions, in which case an alignment defect of the liquid crystals is prevented from being generated in a boundary portion of these regions and undesired light leakage can be suppressed.

At a connection portion 207, the electrode 311b is electrically connected to a conductive layer 222a included in the transistor 206 via a conductive layer 221b. The transistor 206 has a function of controlling the driving of the liquid crystal element 180.

A connection portion 252 is provided in part of a region where the adhesive layer 141 is provided. In the connection portion 252, a conductive layer obtained by processing the same conductive film as the electrode 311a is electrically connected to part of the electrode 113 with the connector 243. Accordingly, a signal or a potential input from the FPC 372 connected to the substrate 351 side can be supplied to the electrode 113 formed on the substrate 361 side through the connection portion 252.

As the connector 243, for example, a conductive particle can be used. As the conductive particle, a particle of an organic resin, silica, or the like coated with a metal material can be used. It is preferable to use nickel or gold as the metal material because contact resistance can be decreased. It is also preferable to use a particle coated with layers of two or more kinds of metal materials, such as a particle coated with nickel and further with gold. A material capable of elastic deformation or plastic deformation is preferably used for the connector 243. As illustrated in FIG. 13, the connector 243, which is the conductive particle, has a shape that is vertically crushed in some cases. With the crushed shape, the contact area between the connector 243 and a conductive layer electrically connected to the connector 243 can be increased, thereby reducing contact resistance and suppressing the generation of problems such as disconnection.

The connector 243 is preferably provided so as to be covered with the adhesive layer 141. For example, the connectors 243 are dispersed in the adhesive layer 141 before curing of the adhesive layer 141.

The light-emitting element 170 is a bottom-emission light-emitting element. The light-emitting element 170 has a stacked-layer structure in which the electrode 191, the EL layer 192, and the electrode 193 are stacked in this order from the insulating layer 220 side. The electrode 191 is connected to a conductive layer 222b included in the transistor 205 through an opening provided in the insulating layer 214. The transistor 205 has a function of controlling the driving of the light-emitting element 170. The insulating layer 216 covers an end portion of the electrode 191. The electrode 193 includes a material that reflects visible light, and the electrode 191 includes a material that transmits visible light. The insulating layer 194 is provided to cover the electrode 193. Light is emitted from the light-emitting element 170 to the substrate 361 side through the coloring layer 134, the insulating layer 220, the opening 451, the electrode 311a, and the like.

The liquid crystal element 180 and the light-emitting element 170 can exhibit various colors when the color of the coloring layer varies among pixels. The display device 300 can display a color image using the liquid crystal element 180. The display device 300 can display a color image using the light-emitting element 170.

The transistor 201, the transistor 203, the transistor 205, and the transistor 206 are formed on a plane of the insulating layer 220 on the substrate 351 side. These transistors can be fabricated through the same process.

The transistor 203 is used for controlling whether the pixel is selected or not (such a transistor is also referred to as a switching transistor or a selection transistor). The transistor 205 is used for controlling a current flowing to the light-emitting element 170 (such a transistor is also referred to as a driving transistor).

Insulating layers such as an insulating layer 211, an insulating layer 212, an insulating layer 213, and the insulating layer 214 are provided on the substrate 351 side of the insulating layer 220. Part of the insulating layer 211 functions as a gate insulating layer of each transistor. The insulating layer 212 is provided to cover the transistor 206 and the like. The insulating layer 213 is provided to cover the transistor 205 and the like. The insulating layer 214 functions as a planarization layer. Note that the number of insulating layers covering the transistor is not limited and may be one or two or more.

A material through which impurities such as water or hydrogen do not easily diffuse is preferably used for at least one of the insulating layers that cover the transistors. This is because such an insulating layer can serve as a barrier film. Such a structure can effectively suppress diffusion of the impurities into the transistors from the outside, and a highly reliable display device can be provided.

Each of the transistors 201, 203, 205, and 206 includes a conductive layer 221a functioning as a gate, the insulating layer 211 functioning as the gate insulating layer, the conductive layer 222a and the conductive layer 222b functioning as a source and a drain, and a semiconductor layer 231. Here, a plurality of layers obtained by processing the same conductive film are shown with the same hatching pattern.

The transistor 201 and the transistor 205 each include a conductive layer 223 functioning as a gate, in addition to the components of the transistor 203 or the transistor 206.

The structure in which the semiconductor layer where a channel is formed is provided between two gates is used as an example of the transistors 201 and 205. Such a structure enables the control of the threshold voltages of transistors. The two gates may be connected to each other and supplied with the same signal to operate the transistors. Such transistors can have higher field-effect mobility and thus have higher on-state current than other transistors. Consequently, a circuit capable of high-speed operation can be obtained. Furthermore, the area occupied by a circuit portion can be reduced. The use of the transistor having high on-state current can reduce signal delay in wirings and can reduce display unevenness even in a display device in which the number of wirings is increased because of increase in size or definition.

Alternatively, by supplying a potential for controlling the threshold voltage to one of the two gates and a potential for driving to the other, the threshold voltage of the transistors can be controlled.

There is no limitation on the structure of the transistors included in the display device. The transistor included in the circuit 364 and the transistor included in the display portion 362 may have the same structure or different structures. A plurality of transistors included in the circuit 364 may have the same structure or a combination of two or more kinds of structures. Similarly, a plurality of transistors included in the display portion 362 may have the same structure or a combination of two or more kinds of structures.

It is preferable to use a conductive material containing an oxide for the conductive layer 223. A conductive film used for the conductive layer 223 is formed under an atmosphere containing oxygen, whereby oxygen can be supplied to the insulating layer 212. The proportion of an oxygen gas in a deposition gas is preferably higher than or equal to 90% and lower than or equal to 100%. Oxygen supplied to the insulating layer 212 is then supplied to the semiconductor layer 231 by later heat treatment; as a result, oxygen vacancies in the semiconductor layer 231 can be reduced.

It is particularly preferable to use a low-resistance oxide semiconductor for the conductive layer 223. In that case, an insulating film that releases hydrogen, such as a silicon nitride film, is preferably used for the insulating layer 213, for example, because hydrogen can be supplied to the conductive layer 223 during the formation of the insulating layer 213 or by heat treatment performed after the formation of the insulating layer 213, which leads to an effective reduction in the electric resistance of the conductive layer 223.

The coloring layer 134 is provided in contact with the insulating layer 213. The coloring layer 134 is covered with the insulating layer 214.

A connection portion 204 is provided in a region where the substrate 351 does not overlap with the substrate 361. In the connection portion 204, the wiring 365 is electrically connected to the FPC 372 via a connection layer 242. The connection portion 204 has a similar structure to the connection portion 207. On the top surface of the connection portion 204, a conductive layer obtained by processing the same conductive film as the electrode 311a is exposed. Thus, the connection portion 204 and the FPC 372 can be electrically connected to each other via the connection layer 242.

As the polarizing plate 135 provided on the outer surface of the substrate 361, a linear polarizing plate or a circularly polarizing plate can be used. An example of a circularly polarizing plate is a stack including a linear polarizing plate and a quarter-wave retardation plate. Such a structure can reduce reflection of external light. The cell gap, alignment, drive voltage, and the like of the liquid crystal element used as the liquid crystal element 180 are controlled depending on the kind of the polarizing plate so that desirable contrast is obtained.

Note that a variety of optical members can be arranged on the outer surface of the substrate 361. Examples of the optical members include a polarizing plate, a retardation plate, a light diffusion layer (e.g., a diffusion film), an anti-reflective layer, and a light-condensing film. Furthermore, an antistatic film preventing the attachment of dust, a water repellent film suppressing the attachment of stain, a hard coat film suppressing generation of a scratch caused by the use, or the like may be arranged on the outer surface of the substrate 361.

For each of the substrates 351 and 361, glass, quartz, ceramic, sapphire, an organic resin, or the like can be used. When the substrates 351 and 361 are formed using a flexible material, the flexibility of the display device can be increased.

A liquid crystal element having, for example, a vertical alignment (VA) mode can be used as the liquid crystal element 180. Examples of the vertical alignment mode include a multi-domain vertical alignment (MVA) mode, a patterned vertical alignment (PVA) mode, and an advanced super view (ASV) mode.

A liquid crystal element having a variety of modes can be used as the liquid crystal element 180. For example, a liquid crystal element using, instead of a VA mode, a twisted nematic (TN) mode, an in-plane switching (IPS) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, or the like can be used.

The liquid crystal element is an element that controls transmission or non-transmission of light utilizing an optical modulation action of the liquid crystal. The optical modulation action of the liquid crystal is controlled by an electric field applied to the liquid crystal (including a horizontal electric field, a vertical electric field, and an oblique electric field). As the liquid crystal used for the liquid crystal element, a thermotropic liquid crystal, a low-molecular liquid crystal, a high-molecular liquid crystal, a polymer dispersed liquid crystal (PDLC), a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

As the liquid crystal material, a positive liquid crystal or a negative liquid crystal may be used, and an appropriate liquid crystal material can be used depending on the mode or design to be used.

To control the alignment of the liquid crystal, the alignment films can be provided. In the case where a horizontal electric field mode is employed, a liquid crystal exhibiting a blue phase for which an alignment film is unnecessary may be used. The blue phase is one of liquid crystal phases, which is generated just before a cholesteric phase changes into an isotropic phase while the temperature of a cholesteric liquid crystal is increased. Since the blue phase appears only in a narrow temperature range, a liquid crystal composition in which several weight percent or more of a chiral material is mixed is used for the liquid crystal in order to improve the temperature range. The liquid crystal composition that includes a liquid crystal exhibiting a blue phase and a chiral material has a short response time and has optical isotropy. In addition, the liquid crystal composition that includes a liquid crystal exhibiting a blue phase and a chiral material does not need alignment treatment and has small viewing angle dependence. An alignment film does not need to be provided and rubbing treatment is thus not necessary; accordingly, electrostatic discharge damage caused by the rubbing treatment can be prevented and defects and damage of the liquid crystal display device in the manufacturing process can be reduced.

In the case where the reflective liquid crystal element is used, the polarizing plate 135 is provided on the display surface side. In addition, a light diffusion plate is preferably provided on the display surface side to improve visibility.

A front light may be provided on the outer side of the polarizing plate 135. As the front light, an edge-light front light is preferably used. A front light including a light-emitting diode (LED) is preferably used to reduce power consumption.

As the adhesive layer, any of a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferred. Alternatively, a two-component-mixture-type resin may be used. Further alternatively, an adhesive sheet or the like may be used.

As the connection layer 242, an anisotropic conductive film (ACF), an anisotropic conductive paste (ACP), or the like can be used.

The light-emitting element 170 may be a top emission, bottom emission, or dual emission light-emitting element, or the like. A conductive film that transmits visible light is used as the electrode through which light is extracted. A conductive film that reflects visible light is preferably used as the electrode through which light is not extracted.

The EL layer 192 includes at least a light-emitting layer. In addition to the light-emitting layer, the EL layer 192 may further include one or more layers containing any of a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like.

Either a low molecular compound or a high molecular compound can be used for the EL layer 192, and an inorganic compound may also be included. The layers included in the EL layer 192 can be formed by any of the following methods: an evaporation method (including a vacuum evaporation method), a transfer method, a printing method, an inkjet method, a coating method, and the like.

The EL layer 192 may contain an inorganic compound such as quantum dots. When quantum dots are used for the light-emitting layer, quantum dots can function as light-emitting materials, for example.

With the use of the combination of a color filter (coloring layer) and a microcavity structure (optical adjustment layer), light with high color purity can be extracted from the display device. The thickness of the optical adjustment layer varies depending on the color of the pixel.

As materials of a gate, a source, and a drain of a transistor, and a conductive layer such as a wiring or an electrode included in a display device, any of metals such as aluminum, titanium, chromium, nickel, copper, yttrium, zirconium, molybdenum, silver, tantalum, and tungsten, or an alloy containing any of these metals as its main component can be used. A single-layer structure or multi-layer structure including a film containing any of these materials can be used.

As a light-transmitting conductive material, a conductive oxide such as indium oxide, indium tin oxide, indium zinc oxide, zinc oxide, or zinc oxide to which gallium is added, or graphene can be used. Alternatively, a metal material such as gold, silver, platinum, magnesium, nickel, tungsten, chromium, molybdenum, iron, cobalt, copper, palladium, or titanium, or an alloy material containing any of these metal materials can be used. Alternatively, a nitride of the metal material (e.g., titanium nitride) or the like may be used. In the case of using the metal material or the alloy material (or the nitride thereof), the thickness is set small enough to be able to transmit light. Alternatively, a stacked film of any of the above materials can be used for the conductive layers. For example, a stacked film of indium tin oxide and an alloy of silver and magnesium is preferably used because the conductivity can be increased. They can also be used for conductive layers such as a variety of wirings and electrodes included in a display device, and conductive layers (e.g., conductive layers serving as a pixel electrode or a common electrode) included in a display element.

Examples of an insulating material that can be used for the insulating layers include a resin such as acrylic or epoxy resin, and an inorganic insulating material such as silicon oxide, silicon oxynitride, silicon nitride oxide, silicon nitride, or aluminum oxide.

Examples of a material that can be used for the coloring layers include a metal material, a resin material, and a resin material containing a pigment or dye.

### [Structure Example 2]

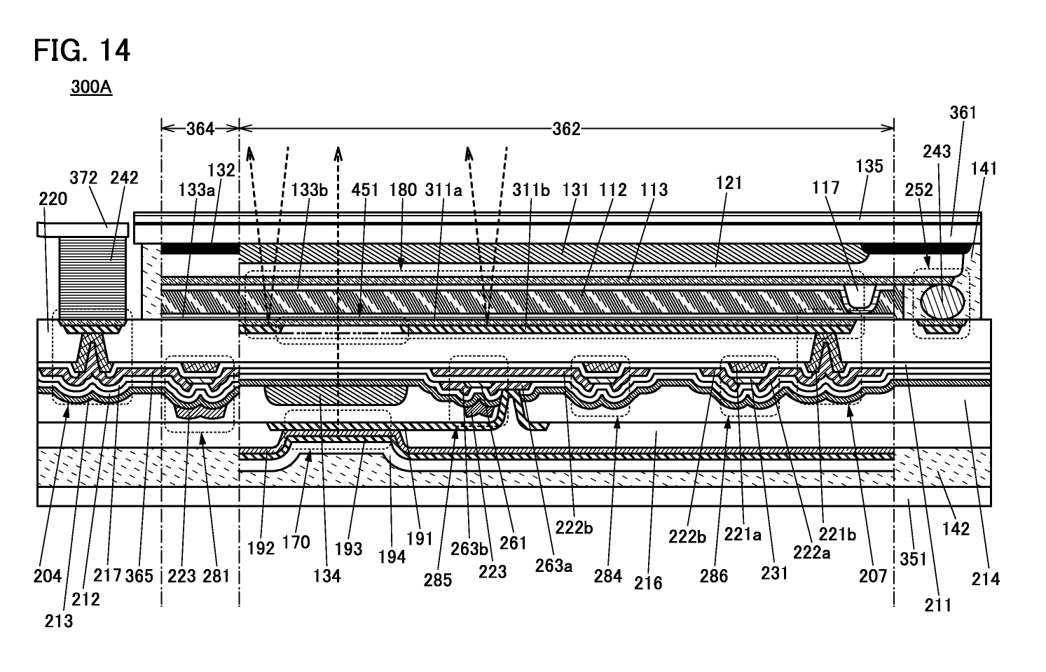

A display device 300A illustrated in FIG. 14 is different from the display device 300 mainly in that a transistor 281, a transistor 284, a transistor 285, and a transistor 286 are included instead of the transistor 201, the transistor 203, the transistor 205, and the transistor 206.

Note that the positions of the insulating layer 117, the connection portion 207, and the like in FIG. 14 are different from those in FIG. 13. FIG. 14 illustrates an end portion of a pixel. The insulating layer 117 is provided so as to overlap with an end portion of the coloring layer 131 and an end portion of the light-blocking layer 132. As in this structure, the insulating layer 117 may be provided in a region not overlapping with a display region (or in a region overlapping with the light-blocking layer 132).

Two transistors included in the display device may partly overlap with each other like the transistor 284 and the transistor 285. In that case, the area occupied by a pixel circuit can be reduced, leading to an increase in resolution. Furthermore, the light-emitting area of the light-emitting element 170 can be increased, leading to an improvement in aperture ratio. The light-emitting element 170 with a high aperture ratio requires low current density to obtain necessary luminance; thus, the reliability is improved.

Each of the transistors 281, 284, and 286 includes the conductive layer 221a, the insulating layer 211, the semiconductor layer 231, the conductive layer 222a, and the conductive layer 222b. The conductive layer 221a overlaps with the semiconductor layer 231 with the insulating layer 211 positioned therebetween. The conductive layer 222a and the conductive layer 222b are electrically connected to the semiconductor layer 231. The transistor 281 includes the conductive layer 223.

The transistor 285 includes the conductive layer 222b, an insulating layer 217, a semiconductor layer 261, the conductive layer 223, the insulating layer 212, the insulating layer 213, a conductive layer 263a, and a conductive layer 263b. The conductive layer 222b overlaps with the semiconductor layer 261 with the insulating layer 217 positioned therebetween. The conductive layer 223 overlaps with the semiconductor layer 261 with the insulating layers 212 and 213 positioned therebetween. The conductive layer 263a and the conductive layer 263b are electrically connected to the semiconductor layer 261.

The conductive layer 221a functions as a gate. The insulating layer 211 functions as a gate insulating layer. The conductive layer 222a functions as one of a source and a drain. The conductive layer 222b functions as the other of the source and the drain.

The conductive layer 222b shared by the transistor 284 and the transistor 285 has a portion functioning as the other of a source and a drain of the transistor 284 and a portion functioning as a gate of the transistor 285. The insulating layer 217, the insulating layer 212, and the insulating layer 213 function as gate insulating layers. One of the conductive layer 263a and the conductive layer 263b functions as a source and the other functions as a drain. The conductive layer 223 functions as a gate.

There is no particular limitation on the structure of the transistor included in the display device of one embodiment of the present invention. For example, a planar transistor, a staggered transistor, or an inverted staggered transistor may be used. A top-gate transistor or a bottom-gate transistor may be used. Gate electrodes may be provided above and below a channel.

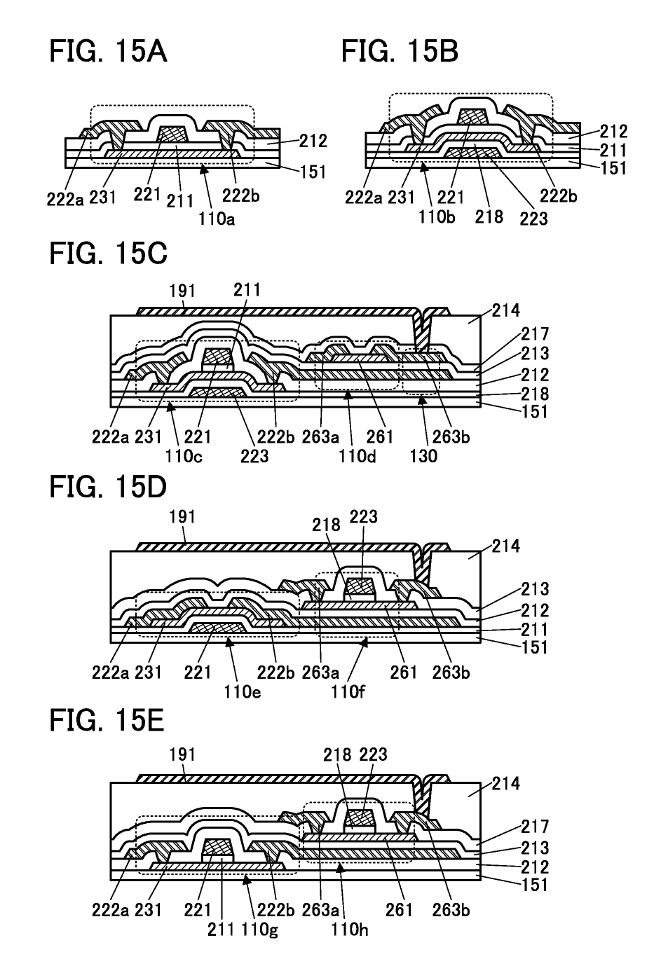

FIGS. 15A to 15E illustrate structure examples of transistors.

A transistor 110a illustrated in FIG. 15A is a top-gate transistor.

The transistor 110a includes a conductive layer 221, the insulating layer 211, the semiconductor layer 231, the insulating layer 212, the conductive layer 222a, and the conductive layer 222b. The semiconductor layer 231 is provided over an insulating layer 151. The conductive layer 221 overlaps with the semiconductor layer 231 with the insulating layer 211 positioned therebetween. The conductive layer 222a and the conductive layer 222b are electrically connected to the semiconductor layer 231 through openings provided in the insulating layer 211 and the insulating layer 212.

The conductive layer 221 functions as a gate. The insulating layer 211 functions as a gate insulating layer. One of the conductive layer 222a and the conductive layer 222b functions as a source and the other functions as a drain.

In the transistor 110a, the conductive layer 221 can be physically distanced from the conductive layer 222a or 222b easily; thus, the parasitic capacitance between the conductive layer 221 and the conductive layer 222a or 222b can be reduced.

A transistor 110b illustrated in FIG. 15B includes, in addition to the components of the transistor 110a, the conductive layer 223 and an insulating layer 218. The conductive layer 223 is provided over the insulating layer 151. The conductive layer 223 overlaps with the semiconductor layer 231. The insulating layer 218 covers the conductive layer 223 and the insulating layer 151.

The conductive layer 223 functions as one of a pair of gates. Thus, the on-state current of the transistor can be increased and the threshold voltage can be controlled.

FIGS. 15C to 15E each illustrate an example of a stacked-layer structure of two transistors. The structures of the two stacked transistors can be independently determined, and the combination of the structures is not limited to those illustrated in FIGS. 15C to 15E.

FIG. 15C illustrates a stacked-layer structure of a transistor 110c and a transistor 110d. The transistor 110c includes two gates. The transistor 110d has a bottom-gate structure. Note that the transistor 110c may have a structure including one gate (top-gate structure). The transistor 110d may include two gates.

The transistor 110c includes the conductive layer 223, the insulating layer 218, the semiconductor layer 231, the conductive layer 221, the insulating layer 211, the conductive layer 222a, and the conductive layer 222b. The conductive layer 223 is provided over the insulating layer 151. The conductive layer 223 overlaps with the semiconductor layer 231 with the insulating layer 218 positioned therebetween. The insulating layer 218 covers the conductive layer 223 and the insulating layer 151. The conductive layer 221 overlaps with the semiconductor layer 231 with the insulating layer 211 positioned therebetween. Although FIG. 15C illustrates an example where the insulating layer 211 is provided only in a region overlapping with the conductive layer 221, the insulating layer 211 may be provided so as to cover an end portion of the semiconductor layer 231, as illustrated in FIG. 15B and other drawings. The conductive layer 222a and the conductive layer 222b are electrically connected to the semiconductor layer 231 through openings provided in the insulating layer 212.

The transistor 110d includes the conductive layer 222b, the insulating layer 213, the semiconductor layer 261, the conductive layer 263a, and the conductive layer 263b. The conductive layer 222b includes a region overlapping with the semiconductor layer 261 with the insulating layer 213 positioned therebetween. The insulating layer 213 covers the conductive layer 222b. The conductive layer 263a and the conductive layer 263b are electrically connected to the semiconductor layer 261.

The conductive layer 221 and the conductive layer 223 each function as a gate of the transistor 110c. The insulating layer 218 and the insulating layer 211 each function as a gate insulating layer of the transistor 110c. The conductive layer 222a functions as one of a source and a drain of the transistor 110c.

The conductive layer 222b has a portion functioning as the other of the source and the drain of the transistor 110c and a portion functioning as a gate of the transistor 110d. The insulating layer 213 functions as a gate insulating layer of the transistor 110d. One of the conductive layer 263a and the conductive layer 263b functions as a source of the transistor 110d and the other functions as a drain of the transistor 110d.

The transistor 110c and the transistor 110d are preferably applied to a pixel circuit of the light-emitting element 170. For example, the transistor 110c can be used as a selection transistor and the transistor 110d can be used as a driving transistor.

The conductive layer 263b is electrically connected to the electrode 191 that functions as a pixel electrode of the light-emitting element through an opening provided in the insulating layer 217 and the insulating layer 214.

FIG. 15D illustrates a stacked-layer structure of a transistor 110e and a transistor 110f The transistor 110e has a bottom-gate structure. The transistor 110f includes two gates. The transistor 110e may include two gates.

The transistor 110e includes the conductive layer 221, the insulating layer 211, the semiconductor layer 231, the conductive layer 222a, and the conductive layer 222b. The conductive layer 221 is provided over the insulating layer 151. The conductive layer 221 overlaps with the semiconductor layer 231 with the insulating layer 211 positioned therebetween. The insulating layer 211 covers the conductive layer 221 and the insulating layer 151. The conductive layer 222a and the conductive layer 222b are electrically connected to the semiconductor layer 231.

The transistor 110f includes the conductive layer 222b, the insulating layer 212, the semiconductor layer 261, the conductive layer 223, the insulating layer 218, the insulating layer 213, the conductive layer 263a, and the conductive layer 263b. The conductive layer 222b includes a region overlapping with the semiconductor layer 261 with the insulating layer 212 positioned therebetween. The insulating layer 212 covers the conductive layer 222b. The conductive layer 263a and the conductive layer 263b are electrically connected to the semiconductor layer 261 through openings provided in the insulating layer 213. The conductive layer 223 overlaps with the semiconductor layer 261 with the insulating layer 218 positioned therebetween. The insulating layer 218 is provided in a region overlapping with the conductive layer 223.

The conductive layer 221 functions as a gate of the transistor 110e. The insulating layer 211 functions as a gate insulating layer of the transistor 110e. The conductive layer 222a functions as one of a source and a drain of the transistor 110e.

The conductive layer 222b has a portion functioning as the other of the source and the drain of the transistor 110e and a portion functioning as a gate of the transistor 110f. The conductive layer 223 functions as another gate of the transistor 110f. The insulating layer 212 and the insulating layer 218 each function as a gate insulating layer of the transistor 110f. One of the conductive layer 263a and the conductive layer 263b functions as a source of the transistor 110f and the other functions as a drain of the transistor 110f.

The conductive layer 263b is electrically connected to the electrode 191 that functions as a pixel electrode of a light-emitting element through an opening provided in the insulating layer 214.

FIG. 15E illustrates a stacked-layer structure of a transistor 110g and a transistor 110h. The transistor 110g has a top-gate structure. The transistor 110h includes two gates. The transistor 110g may include two gates.

The transistor 110g includes the semiconductor layer 231, the conductive layer 221, the insulating layer 211, the conductive layer 222a, and the conductive layer 222b. The semiconductor layer 231 is provided over the insulating layer 151. The conductive layer 221 overlaps with the semiconductor layer 231 with the insulating layer 211 positioned therebetween. The insulating layer 211 overlaps with the conductive layer 221. The conductive layer 222a and the conductive layer 222b are electrically connected to the semiconductor layer 231 through openings provided in the insulating layer 212.

The transistor 110h includes the conductive layer 222b, the insulating layer 213, the semiconductor layer 261, the conductive layer 223, the insulating layer 218, the insulating layer 217, the conductive layer 263a, and the conductive layer 263b. The conductive layer 222b includes a region overlapping with the semiconductor layer 261 with the insulating layer 213 positioned therebetween. The insulating layer 213 covers the conductive layer 222b. The conductive layer 263a and the conductive layer 263b are electrically connected to the semiconductor layer 261 through openings provided in the insulating layer 217. The conductive layer 223 overlaps with the semiconductor layer 261 with the insulating layer 218 positioned therebetween. The insulating layer 218 is provided in a region overlapping with the conductive layer 223.

The conductive layer 221 functions as a gate of the transistor 110g. The insulating layer 211 functions as a gate insulating layer of the transistor 110g. The conductive layer 222a functions as one of a source and a drain of the transistor 110g.

The conductive layer 222b has a portion functioning as the other of the source and the drain of the transistor 110g and a portion functioning as a gate of the transistor 110h. The conductive layer 223 functions as another gate of the transistor 110h. The insulating layer 213 and the insulating layer 218 each function as a gate insulating layer of the transistor 110h. One of the conductive layer 263a and the conductive layer 263b functions as a source of the transistor 110h and the other functions as a drain of the transistor 110h.

The conductive layer 263b is electrically connected to the electrode 191 that functions as a pixel electrode of a light-emitting element through an opening provided in the insulating layer 214.

### [Manufacturing Method Example]

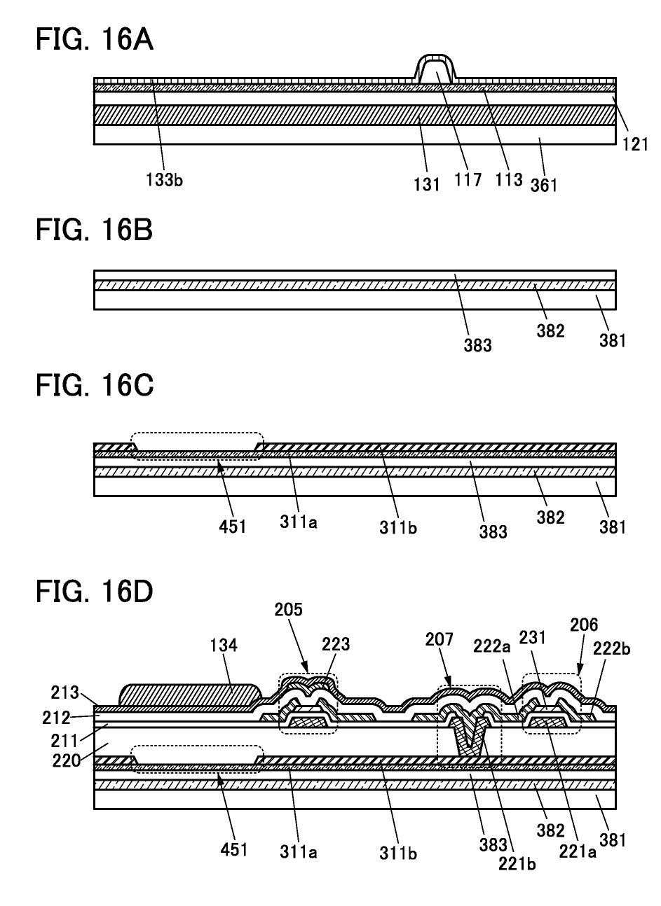

Hereinafter, the method for manufacturing the display device of this embodiment will be specifically described with reference to FIGS. 16A to 16D, FIGS. 17A to 17C, FIGS. 18A and 18B, and FIGS. 19A and 19B.

Note that thin films included in the display device (e.g., insulating films, semiconductor films, or conductive films) can be formed by any of a sputtering method, a chemical vapor deposition (CVD) method, a vacuum evaporation method, a pulsed laser deposition (PLD) method, an atomic layer deposition (ALD) method, and the like. As the CVD method, a plasma-enhanced chemical vapor deposition (PECVD) method or a thermal CVD method may be used. As the thermal CVD method, for example, a metal organic chemical vapor deposition (MOCVD) method may be used.

Alternatively, thin films included in the display device (e.g., insulating films, semiconductor films, or conductive films) can be formed by a method such as spin coating, dipping, spray coating, ink-jetting, dispensing, screen printing, or offset printing, or with a doctor knife, a slit coater, a roll coater, a curtain coater, or a knife coater.

When thin films included in the display device are processed, a lithography method or the like can be used for the processing. Alternatively, island-shaped thin films may be formed by a film formation method using a blocking mask. A nanoimprinting method, a sandblasting method, a lift-off method, or the like may be used for the processing of thin films. Examples of a photolithography method include a method in which a resist mask is formed over a thin film to be processed, the thin film is processed by etching or the like, and the resist mask is removed, and a method in which a photosensitive thin film is formed and exposed to light and developed to be processed into a desired shape.

In the case of using light in the lithography method, any of an i-line (light with a wavelength of 365 nm), a g-line (light with a wavelength of 436 nm), and an h-line (light with a wavelength of 405 nm), or combined light of any of them can be used for exposure. Alternatively, ultraviolet light, KrF laser light, ArF laser light, or the like can be used. Exposure may be performed by liquid immersion exposure technique. As the light for the exposure, extreme ultra-violet (EUV) light or X-rays may be used. Instead of the light for the exposure, an electron beam can be used. It is preferable to use EUV, X-rays, or an electron beam because extremely minute processing can be performed. Note that in the case of performing exposure by scanning of a beam such as an electron beam, a photomask is not needed.

For etching of thin films, a dry etching method, a wet etching method, a sandblast method, or the like can be used.

An example of a manufacturing method of the display device 300 illustrated in FIG. 13 will be described below. The manufacturing method will be described with reference to FIGS. 16A to 16D, FIGS. 17A to 17C, FIGS. 18A and 18B, and FIGS. 19A and 19B, focusing on the display portion 362 of the display device 300.

First, the coloring layer 131 is formed over the substrate 361 (FIG. 16A). The coloring layer 131 is formed using a photosensitive material, in which case the processing into an island shape can be performed by a photolithography method or the like. Note that in the circuit 364 and the like illustrated in FIG. 13, the light-blocking layer 132 is provided over the substrate 361.

Then, the insulating layer 121 is formed over the coloring layer 131 and the light-blocking layer 132.

The insulating layer 121 preferably functions as a planarization layer. A resin such as acrylic or epoxy is suitably used for the insulating layer 121.

An inorganic insulating film may be used for the insulating layer 121. For example, an inorganic insulating film such as a silicon nitride film, a silicon oxynitride film, a silicon oxide film, a silicon nitride oxide film, an aluminum oxide film, or an aluminum nitride film can be used for the insulating layer 121. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Further alternatively, a stack including two or more of the above insulating films may be used.

Next, the electrode 113 is formed. The electrode 113 can be formed in the following manner: a conductive film is formed, a resist mask is formed, the conductive film is etched, and the resist mask is removed. The electrode 113 is formed using a conductive material that transmits visible light.

After that, the insulating layer 117 is formed over the electrode 113. An organic insulating film is preferably used for the insulating layer 117.

Subsequently, the alignment film 133b is formed over the electrode 113 and the insulating layer 117 (FIG. 16A). The alignment film 133b can be formed in the following manner: a thin film is formed using a resin or the like, and then, rubbing treatment is performed.

Note that steps illustrated in FIGS. 16B to 16D, FIGS. 17A to 17C, FIGS. 18A and 18B, and FIG. 19A are performed independently of the steps described with reference to FIG. 16A.

First, a separation layer 382 is formed over a formation substrate 381, and an insulating layer 383 is formed over the separation layer 382 (FIG. 16B).

In this step, a material is selected that would cause separation at the interface between the formation substrate 381 and the separation layer 382, the interface between the separation layer 382 and the insulating layer 383, or in the separation layer 382 when the formation substrate 381 is peeled. In this embodiment, an example in which separation occurs at the interface between the insulating layer 383 and the separation layer 382 is described; however, one embodiment of the present invention is not limited to such an example and depends on a material used for the separation layer 382 or the insulating layer 383.

The formation substrate 381 has stiffness high enough for easy transfer and has resistance to heat applied in the manufacturing process. Examples of a material that can be used for the formation substrate 381 include glass, quartz, ceramics, sapphire, a resin, a semiconductor, a metal, and an alloy. Examples of the glass include alkali-free glass, barium borosilicate glass, and aluminoborosilicate glass.

The separation layer 382 can be formed using an organic material or an inorganic material.

Examples of an inorganic material that can be used for the separation layer 382 include a metal containing an element selected from tungsten, molybdenum, titanium, tantalum, niobium, nickel, cobalt, zirconium, zinc, ruthenium, rhodium, palladium, osmium, iridium, and silicon; an alloy containing any of the above elements; and a compound containing any of the above elements. A crystal structure of a layer containing silicon may be amorphous, microcrystal, or polycrystal.

In the case of using an inorganic material, the thickness of the separation layer 382 is greater than or equal to 1 nm and less than or equal to 1000 nm, preferably greater than or equal to 10 nm and less than or equal to 200 nm, and further preferably greater than or equal to 10 nm and less than or equal to 100 nm.

In the case of using an inorganic material, the separation layer 382 can be formed by a sputtering method, a CVD method, an ALD method, or an evaporation method, for example.

Examples of an organic material that can be used for the separation layer 382 include an acrylic resin, an epoxy resin, a polyamide resin, a polyimide-amide resin, a siloxane resin, a benzocyclobutene-based resin, and a phenol resin.

In the case of using an organic material, the thickness of the separation layer 382 is preferably greater than or equal to 0.01 μm and less than 10 μm, further preferably greater than or equal to 0.1 μm and less than or equal to 3 μm, and still further preferably greater than or equal to 0.5 μm and less than or equal to 1 μm. The separation layer 382 whose thickness is within the above range can lead to a reduction in manufacturing cost. The thickness of the separation layer 382 is not necessarily within the above range and may be greater than or equal to 10 μm: for example, greater than or equal to 10 μm and less than or equal to 200 μm.

In the case of using an organic material, the separation layer 382 can be formed by a method such as spin coating, dipping, spray coating, ink-jetting, dispensing, screen printing, or offset printing, or with a doctor knife, a slit coater, a roll coater, a curtain coater, or a knife coater, for example.

An inorganic insulating film is preferably formed using the insulating layer 383. For example, an inorganic insulating film such as a silicon nitride film, a silicon oxynitride film, a silicon oxide film, a silicon nitride oxide film, an aluminum oxide film, or an aluminum nitride film can be used for the insulating layer 383. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Further alternatively, a stack including two or more of the above insulating films may be used.

For example, a stacked-layer structure of a layer containing a high-melting-point metal material such as tungsten and a layer containing an oxide of the metal material may be used for the separation layer 382, and a stacked-layer structure of a plurality of inorganic insulating films containing silicon nitride, silicon oxynitride, silicon nitride oxide, or the like may be used for the insulating layer 383. When a high-melting-point metal material is used for the separation layer 382, layers formed after the separation layer 382 can be formed at higher temperatures; thus, impurity concentration can be reduced and a highly reliable display device can be fabricated. A step for removing a layer unnecessary for the display device (e.g., the separation layer 382 or the insulating layer 383) may be performed after the peeling. The separation layer 382 or the insulating layer 383 is not necessarily removed and may be used as a component of the display device.

Next, the electrode 311a is formed over the insulating layer 383, and the electrode 311b is formed over the electrode 311a (FIG. 16C). The electrode 311b includes the opening 451 over the electrode 311a. Each of the electrodes 311a and 311b can be formed in the following manner: a conductive film is formed, a resist mask is formed, the conductive film is etched, and the resist mask is removed. The electrode 311a is formed using a conductive material that transmits visible light. The electrode 311b is formed using a conductive material that reflects visible light.

After that, the insulating layer 220 is formed (FIG. 16D). Then, an opening that reaches the electrode 311b is formed in the insulating layer 220.

The insulating layer 220 can be used as a barrier layer that prevents diffusion of impurities contained in the separation layer 382 into the transistor and the display element formed later. In the case of using an organic material for the separation layer 382, the insulating layer 220 preferably prevents diffusion of moisture or the like contained in the separation layer 382 into the transistor and the display element when the separation layer 382 is heated. Thus, the insulating layer 220 preferably has a high barrier property.

The insulating layer 220 can be formed using the inorganic insulating film, the resin, or the like that can be used for the insulating layer 121.

Next, the transistor 205 and the transistor 206 are formed over the insulating layer 220.

There is no particular limitation on a semiconductor material used for the semiconductor layer of the transistor, and for example, a Group 14 element, a compound semiconductor, or an oxide semiconductor can be used. Typically, a semiconductor containing silicon, a semiconductor containing gallium arsenide, an oxide semiconductor containing indium, or the like can be used.

Described here is the case where a bottom-gate transistor including an oxide semiconductor layer as the semiconductor layer 231 is fabricated as the transistor 206. The transistor 205 includes the conductive layer 223 and the insulating layer 212 in addition to the components of the transistor 206, and has two gates.

An oxide semiconductor is preferably used for the semiconductor layer of the transistor. The use of a semiconductor material having a wider band gap and a lower carrier density than silicon can reduce the off-state current of the transistor.

Specifically, first, the conductive layer 221a and the conductive layer 221b are formed over the insulating layer 220. The conductive layer 221a and the conductive layer 221b can be formed in the following manner: a conductive film is formed, a resist mask is formed, the conductive film is etched, and the resist mask is removed. At this time, the conductive layer 221b and the electrode 311b are connected to each other through an opening in the insulating layer 220.

Next, the insulating layer 211 is formed.

For the insulating layer 211, for example, an inorganic insulating film such as a silicon nitride film, a silicon oxynitride film, a silicon oxide film, a silicon nitride oxide film, an aluminum oxide film, or an aluminum nitride film can be used. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Further alternatively, a stack including two or more of the above insulating films may be used.

An inorganic insulating film is preferably formed at high temperatures because the film can have higher density and a higher barrier property as the deposition temperature becomes higher. The substrate temperature during the deposition of the inorganic insulating film is preferably higher than or equal to room temperature (25° C.) and lower than or equal to 350° C., and further preferably higher than or equal to 100° C. and lower than or equal to 300° C.

Then, the semiconductor layer 231 is formed. In this embodiment, an oxide semiconductor layer is formed as the semiconductor layer 231. The oxide semiconductor layer can be formed in the following manner: an oxide semiconductor film is formed, a resist mask is formed, the oxide semiconductor film is etched, and the resist mask is removed.

The substrate temperature during the deposition of the oxide semiconductor film is preferably lower than or equal to 350° C., further preferably higher than or equal to room temperature and lower than or equal to 200° C., and still further preferably higher than or equal to room temperature and lower than or equal to 130° C.

The oxide semiconductor film can be formed using either one of an inert gas and an oxygen gas. Note that there is no particular limitation on the percentage of oxygen flow rate (partial pressure of oxygen) at the time of forming the oxide semiconductor film. To fabricate a transistor having high field-effect mobility, however, the percentage of oxygen flow rate (partial pressure of oxygen) at the time of forming the oxide semiconductor film is preferably higher than or equal to 0% and lower than or equal to 30%, further preferably higher than or equal to 5% and lower than or equal to 30%, and still further preferably higher than or equal to 7% and lower than or equal to 15%.

The oxide semiconductor film preferably contains at least indium or zinc. It is particularly preferable to contain indium and zinc.

The energy gap of the oxide semiconductor is preferably 2 eV or more, further preferably 2.5 eV or more, and still further preferably 3 eV or more. The use of such an oxide semiconductor having a wide energy gap leads to a reduction in off-state current of a transistor.

The oxide semiconductor film can be formed by a sputtering method. Alternatively, a PLD method, a PECVD method, a thermal CVD method, an ALD method, a vacuum evaporation method, or the like may be used.

Note that an example of an oxide semiconductor is described in Embodiment 4.

Next, the conductive layer 222a and the conductive layer 222b are formed. The conductive layer 222a and the conductive layer 222b can be formed in the following manner: a conductive film is formed, a resist mask is formed, the conductive film is etched, and the resist mask is removed. Each of the conductive layers 222a and 222b is connected to the semiconductor layer 231. Here, the conductive layer 222a included in the transistor 206 is electrically connected to the conductive layer 221b. As a result, the electrode 311b and the conductive layer 222a can be electrically connected to each other at the connection portion 207.

Note that during the processing of the conductive layer 222a and the conductive layer 222b, the semiconductor layer 231 might be partly etched to be thin in a region not covered by the resist mask.

In the above manner, the transistor 206 can be fabricated (FIG. 16D). In the transistor 206, part of the conductive layer 221a functions as a gate, part of the insulating layer 211 functions as a gate insulating layer, and the conductive layer 222a and the conductive layer 222b function as a source and a drain.

Next, the insulating layer 212 that covers the transistor 206 is formed, and the conductive layer 223 is formed over the insulating layer 212.

The insulating layer 212 can be formed in a manner similar to that of the insulating layer 211.

The conductive layer 223 included in the transistor 205 can be formed in the following manner: a conductive film is formed, a resist mask is formed, the conductive film is etched, and the resist mask is removed.

In the above manner, the transistor 205 can be fabricated (FIG. 16D). In the transistor 205, part of the conductive layer 221a and part of the conductive layer 223 function as gates, part of the insulating layer 211 and part of the insulating layer 212 function as gate insulating layers, and the conductive layer 222a and the conductive layer 222b function as a source and a drain.

Next, the insulating layer 213 is formed (FIG. 16D). The insulating layer 213 can be formed in a manner similar to that of the insulating layer 211.

It is preferable to use an oxide insulating film formed in an atmosphere containing oxygen, such as a silicon oxide film or a silicon oxynitride film, for the insulating layer 212. An insulating film with low oxygen diffusibility and oxygen permeability, such as a silicon nitride film, is preferably stacked as the insulating layer 213 over the silicon oxide film or the silicon oxynitride film. The oxide insulating film formed in an atmosphere containing oxygen can easily release a large amount of oxygen by heating. When a stack including such an oxide insulating film that releases oxygen and an insulating film with low oxygen diffusibility and oxygen permeability is heated, oxygen can be supplied to the oxide semiconductor layer. As a result, oxygen vacancies in the oxide semiconductor layer can be filled and defects at the interface between the oxide semiconductor layer and the insulating layer 212 can be repaired, leading to a reduction in defect levels. Accordingly, an extremely highly reliable display device can be fabricated.

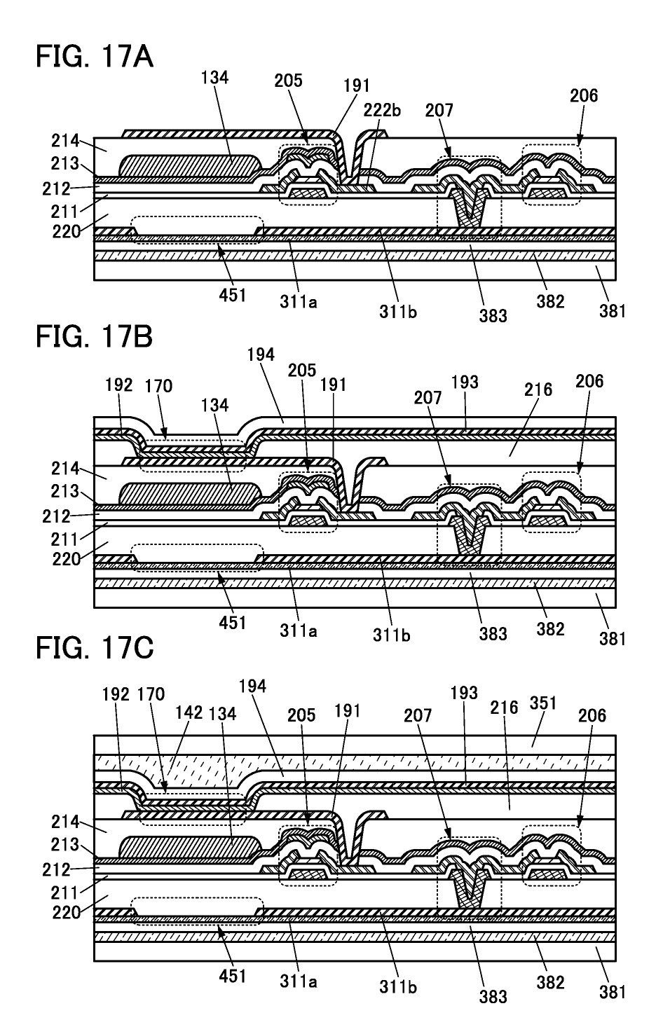

Next, the coloring layer 134 is formed over the insulating layer 213 (FIG. 16D), and then, the insulating layer 214 is formed (FIG. 17A). The coloring layer 134 is positioned so as to overlap with the opening 451 in the electrode 311b.

The coloring layer 134 can be formed in a manner similar to that of the coloring layer 131. The display element is formed on the insulating layer 214 in a later step; thus, the insulating layer 214 preferably functions as a planarization layer. For the insulating layer 214, the description of the resin or the inorganic insulating film that can be used for the insulating layer 121 can be referred to.

After that, an opening that reaches the conductive layer 222b included in the transistor 205 is formed in the insulating layer 212, the insulating layer 213, and the insulating layer 214.

Subsequently, the electrode 191 is formed (FIG. 17A). The electrode 191 can be formed in the following manner: a conductive film is formed, a resist mask is formed, the conductive film is etched, and the resist mask is removed. Here, the conductive layer 222b included in the transistor 205 and the electrode 191 are connected to each other. The electrode 191 is formed using a conductive material that transmits visible light.

Then, the insulating layer 216 that covers the end portion of the electrode 191 is formed (FIG. 17B). For the insulating layer 216, the description of the resin or the inorganic insulating film that can be used for the insulating layer 121 can be referred to. The insulating layer 216 includes an opening in a region overlapping with the electrode 191.

Next, the EL layer 192 and the electrode 193 are formed (FIG. 17B). Part of the electrode 193 functions as the common electrode of the light-emitting element 170. The electrode 193 is formed using a conductive material that reflects visible light.

The EL layer 192 can be formed by an evaporation method, a coating method, a printing method, a discharge method, or the like. In the case where the EL layer 192 is formed for each individual pixel, an evaporation method using a shadow mask such as a metal mask, an ink-jet method, or the like can be used. In the case of sharing the EL layer 192 by some pixels, an evaporation method not using a metal mask can be used.

Either a low molecular compound or a high molecular compound can be used for the EL layer 192, and an inorganic compound may also be included.

Steps after the formation of the EL layer 192 are performed such that temperatures higher than the heat resistant temperature of the EL layer 192 are not applied to the EL layer 192. The electrode 193 can be formed by an evaporation method, a sputtering method, or the like.

In the above manner, the light-emitting element 170 can be formed (FIG. 17B). In the light-emitting element 170, the electrode 191 part of which functions as the pixel electrode, the EL layer 192, and the electrode 193 part of which functions as the common electrode are stacked. The light-emitting element 170 is formed such that the light-emitting region overlaps with the coloring layer 134 and the opening 451 in the electrode 311b.

Although an example where a bottom-emission light-emitting element is formed as the light-emitting element 170 is described here, one embodiment of the present invention is not limited thereto.

The light-emitting element may be a top emission, bottom emission, or dual emission light-emitting element. A conductive film that transmits visible light is used as the electrode through which light is extracted. A conductive film that reflects visible light is preferably used as the electrode through which light is not extracted.

Next, the insulating layer 194 is formed so as to cover the electrode 193 (FIG. 17B). The insulating layer 194 functions as a protective layer that prevents diffusion of impurities such as water into the light-emitting element 170. The light-emitting element 170 is sealed with the insulating layer 194. After the electrode 193 is formed, the insulating layer 194 is preferably formed without exposure to the air.

The inorganic insulating film that can be used for the insulating layer 121 can be used for the insulating layer 194, for example. It is particularly preferable that the insulating layer 194 include an inorganic insulating film with a high barrier property. A stack including an inorganic insulating film and an organic insulating film can also be used.

The insulating layer 194 is preferably formed at substrate temperature lower than or equal to the heat resistant temperature of the EL layer 192. The insulating layer 194 can be formed by an ALD method, a sputtering method, or the like. An ALD method and a sputtering method are preferable because a film can be formed at low temperatures. An ALD method is preferable because the coverage of the insulating layer 194 is improved.

Then, the substrate 351 is bonded to a surface of the insulating layer 194 with the adhesive layer 142 (FIG. 17C).

As the adhesive layer 142, any of a variety of curable adhesives such as a reactive curable adhesive, a thermosetting adhesive, an anaerobic adhesive, and a photocurable adhesive such as an ultraviolet curable adhesive can be used. Alternatively, an adhesive sheet or the like may be used.

For the substrate 351, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Any of a variety of materials such as glass, quartz, a resin, a metal, an alloy, and a semiconductor can be used for the substrate 351. The substrate 351 formed using any of a variety of materials such as glass, quartz, a resin, a metal, an alloy, and a semiconductor may be thin enough to be flexible.

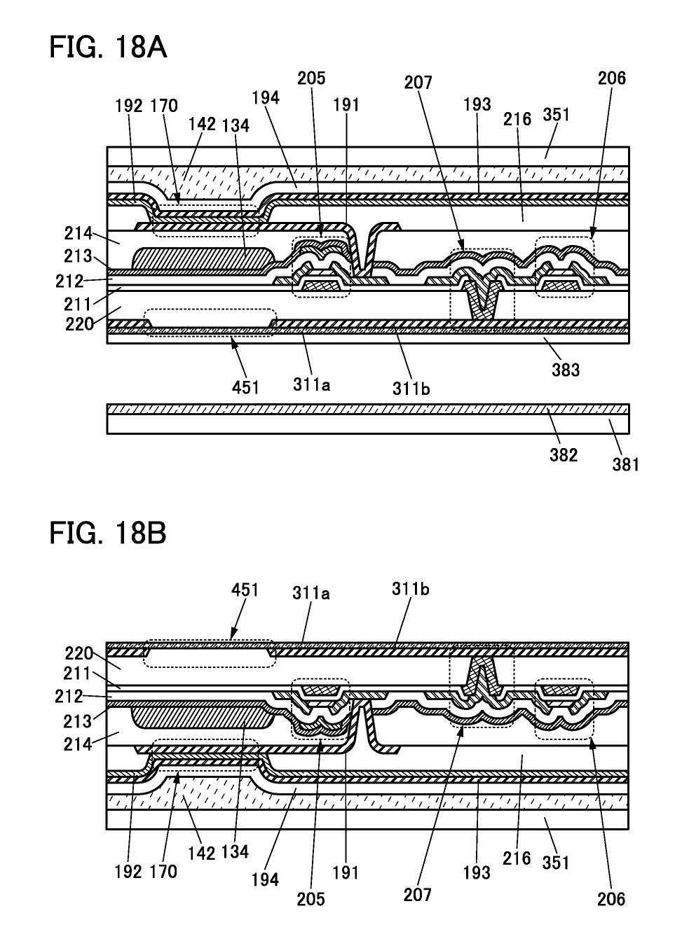

After that, the formation substrate 381 is peeled (FIG. 18A).

The position of the separation surface depends on the materials, the formation methods, and the like of the insulating layer 383, the separation layer 382, the formation substrate 381, and the like.

FIG. 18A illustrates an example where the separation occurs at the interface between the separation layer 382 and the insulating layer 383. By the separation, the insulating layer 383 is exposed.

Before the separation, a separation trigger may be formed in the separation layer 382. For example, part of or the entire separation layer 382 may be irradiated with laser light, in which case the separation layer 382 can be embrittled or the adhesion between the separation layer 382 and the insulating layer 383 (or the formation substrate 381) can be reduced.

The formation substrate 381 can be peeled by applying a perpendicular tensile force to the separation layer 382, for example. Specifically, the formation substrate 381 can be peeled by pulling up the substrate 351 by part of its suction-attached top surface.

The separation trigger may be formed by inserting a sharp instrument such as a knife between the separation layer 382 and the insulating layer 383 (or the formation substrate 381). Alternatively, the separation trigger may be formed by cutting the separation layer 382 from the substrate 351 side with a sharp instrument.

Next, the insulating layer 383 is removed. The insulating layer 383 can be removed by a dry etching method, for example. Accordingly, the electrode 311a is exposed (FIG. 18B).

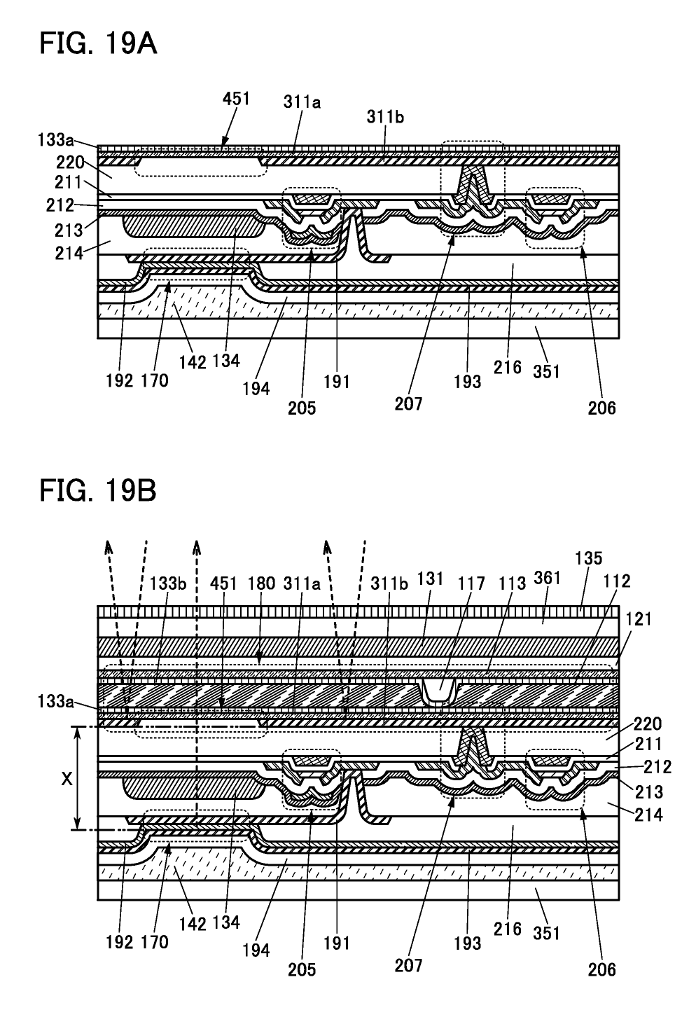

Subsequently, the alignment film 133a is formed on the exposed surface of the electrode 311a (FIG. 19A). The alignment film 133a can be formed in the following manner: a thin film is formed using a resin or the like, and then, rubbing treatment is performed.

Then, the substrate 361 obtained from the steps described using FIG. 16A and the substrate 351 obtained from the steps up to the step illustrated in FIG. 19A are bonded to each other with the liquid crystal 112 provided therebetween (FIG. 19B). Although not illustrated in FIG. 19B, the substrate 351 and the substrate 361 are bonded to each other with the adhesive layer 141 as illustrated in FIG. 13 and other drawings. For materials of the adhesive layer 141, the description of the materials that can be used for the adhesive layer 142 can be referred to.

In the liquid crystal element 180 illustrated in FIG. 19B, the electrode 311a (and the electrode 311b) part of which functions as the pixel electrode, the liquid crystal 112, and the electrode 113 part of which functions as the common electrode are stacked. The liquid crystal element 180 is formed so as to overlap with the coloring layer 131.

Through the above steps, the display device 300 can be fabricated.

The display device of this embodiment includes two types of display elements as described above; thus, switching between a plurality of display modes is possible. Accordingly, the display device can have high visibility and convenience regardless of the ambient brightness.

In the case where a plurality of structure examples are described in one embodiment in this specification, some of the structure examples can be combined as appropriate.

At least part of this embodiment can be implemented in combination with any of the other embodiments described in this specification as appropriate.

### Embodiment 5

In this embodiment, described below is the composition of a cloud-aligned composite oxide semiconductor (CAC-OS) applicable to a transistor disclosed in one embodiment of the present invention.

The CAC-OS has, for example, a composition in which elements included in an oxide semiconductor are unevenly distributed. Materials including unevenly distributed elements each have a size of greater than or equal to 0.5 nm and less than or equal to 10 nm, preferably greater than or equal to 1 nm and less than or equal to 2 nm, or a similar size. Note that in the following description of an oxide semiconductor, a state in which one or more metal elements are unevenly distributed and regions including the metal element(s) are mixed is referred to as a mosaic pattern or a patch-like pattern. The region has a size of greater than or equal to 0.5 nm and less than or equal to 10 nm, preferably greater than or equal to 1 nm and less than or equal to 2 nm, or a similar size.

Note that an oxide semiconductor preferably contains at least indium. In particular, indium and zinc are preferably contained. In addition, one or more of aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For example, of the CAC-OS, an In—Ga—Zn oxide with the CAC composition (such an In—Ga—Zn oxide may be particularly referred to as CAC-IGZO) has a composition in which indium oxide (InO_{X1}, where X1 is a real number greater than 0) or indium zinc oxide (In_{X2}Zn_{Y2}O_{Z2}, where X2, Y2, and Z2 are real numbers greater than 0) forming a mosaic pattern is evenly distributed in the film (this composition is also referred to as a cloud-like composition). The mosaic pattern is formed by separating the materials into InO_{X1} or In_{X2}Zn_{Y2}O_{Z2} and gallium oxide (GaO_{X3}, where X3 is a real number greater than 0) or gallium zinc oxide (Ga_{X4}Zn_{Y4}O_{Z4}, where X4, Y4, and Z4 are real numbers greater than 0), for example.

That is, the CAC-OS is a composite oxide semiconductor with a composition in which a region including GaO_{X3} as a main component and a region including In_{X2}Zn_{Y2}O_{Z2}or InO_{X1} as a main component are mixed. Note that in this specification, for example, when the atomic ratio of In to an element M in a first region is greater than the atomic ratio of In to an element M in a second region, the first region is described as having higher In concentration than the second region.

Note that a compound including In, Ga, Zn, and O is also known as IGZO. Typical examples of IGZO include a crystalline compound represented by InGaO₃(ZnO)ₘ₁ (m1 is a natural number) and a crystalline compound represented by In₍₁₊ₓ₀₎Ga₍₁₋ₓ₀₎O₃(ZnO)ₘ₀ (−1≦x0≦1; m0 is a given number).

The above crystalline compounds have a single crystal structure, a polycrystalline structure, or a CAAC structure. Note that the CAAC structure is a crystal structure in which a plurality of IGZO nanocrystals have c-axis alignment and are connected in the a-b plane direction without alignment.

The CAC-OS relates to the material composition of an oxide semiconductor. In a material composition of a CAC-OS including In, Ga, Zn, and O, nanoparticle regions including Ga as a main component are observed in part of the CAC-OS and nanoparticle regions including In as a main component are observed in part thereof. These nanoparticle regions are randomly dispersed to form a mosaic pattern. Therefore, the crystal structure is a secondary element for the CAC-OS.

Note that in the CAC-OS, a stacked-layer structure including two or more films with different atomic ratios is not included. For example, a two-layer structure of a film including In as a main component and a film including Ga as a main component is not included.

A boundary between the region including GaO_{X3} as a main component and the region including In_{X2}Zn_{Y2}O_{Z2} or InO_{X1} as a main component is not clearly observed in some cases.

In the case where one or more of aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium in a CAC-OS, nanoparticle regions including the selected element(s) as a main component(s) are observed in part of the CAC-OS and nanoparticle regions including In as a main component are observed in part of the CAC-OS, and these nanoparticle regions are randomly dispersed to form a mosaic pattern in the CAC-OS.

The CAC-OS can be formed by a sputtering method under a condition where a substrate is not heated intentionally. In the case where the CAC-OS is formed by a sputtering method, one or more of an inert gas (typically, argon), an oxygen gas, and a nitrogen gas are used as a deposition gas. Furthermore, the flow rate of the oxygen gas to the total flow rate of the deposition gas in deposition is preferably as low as possible, for example, the flow rate of the oxygen gas is higher than equal to 0% and lower than 30%, preferably higher than equal to 0% and lower than or equal to 10%.

The CAC-OS is characterized in that a clear peak is not observed when measurement is conducted using a θ/2 θ scan by an out-of-plane method with an X-ray diffraction (XRD). That is, it is found by the XRD that there are no alignment in the a-b plane direction and no alignment in the c-axis direction in the measured areas.

In the CAC-OS, an electron diffraction pattern that is obtained by irradiation with an electron beam with a probe diameter of 1 nm (also referred to as nanobeam electron beam) has regions with high luminance in a ring pattern and a plurality of bright spots appear in the ring-like pattern. Thus, it is found from the electron diffraction pattern that the crystal structure of the CAC-OS includes a nanocrystalline (nc) structure that does not show alignment in the plane direction and the cross-sectional direction.

For example, energy dispersive X-ray spectroscopy (EDX) is used to obtain EDX mapping, and according to the EDX mapping, the CAC-OS of the In—Ga—Zn oxide has a composition in which the regions including GaO_{X3} as a main component and the regions including In_{X2}Zn_{Y2}O_{Z2} or InO_{X1} as a main component are unevenly distributed and mixed.

The CAC-OS has a structure different from that of an IGZO compound in which metal elements are evenly distributed, and has characteristics different from those of the IGZO compound. That is, in the CAC-OS, regions including GaO_{X3} or the like as a main component and regions including In_{X2}Zn_{Y2}O_{Z2} or InO_{X1} as a main component are separated to form a mosaic pattern.

The conductivity of a region including In_{X2}Zn_{Y2}O_{Z2} or InO_{X1} as a main component is higher than that of a region including GaO_{X3} or the like as a main component. In other words, when carriers flow through regions including In_{X2}Zn_{Y2}O_{Z2} or InO_{X1} as a main component, the conductivity of an oxide semiconductor is generated. Accordingly, when regions including In_{X2}Zn_{Y2}O_{Z2} or InO_{X1} as a main component are distributed in an oxide semiconductor like a cloud, high field-effect mobility (Iₒₙ) can be achieved.

In contrast, the insulating property of a region including GaO_{X3} or the like as a main component is higher than that of a region including In_{X2}Zn_{Y2}O_{Z2}or InO_{X1} as a main component. In other words, when regions including GaO_{X3} or the like as a main component are distributed in an oxide semiconductor, leakage current can be suppressed and favorable switching operation can be achieved.

Accordingly, when a CAC-OS is used in a semiconductor element, the insulating property derived from GaO_{X3} or the like and the conductivity derived from In_{X2}Zn_{Y2}O_{Z2} or InO_{X1} complement each other, whereby high on-state current (Iₒₙ) and high field-effect mobility (μ) can be achieved.

A semiconductor element including a CAC-OS has high reliability. Thus, the CAC-OS is suitably used in a variety of semiconductor devices typified by a display.

At least part of this embodiment can be implemented in combination with any of the other embodiments described in this specification as appropriate.

### [Example] W20

In this example, simulation results of the method for driving the electronic device described in Embodiment 1 with the use of a display device including a first display element and a second display element are described. Note that the first display element and the second display element included in the display device are a reflective liquid crystal element and a light-emitting element, respectively.

The display device includes a display portion which includes a first pixel expressing gray scales by controlling the amount of light reflected by the first display element and a second pixel expressing gray scales by controlling the amount of light emitted by the second display element. The display portion is configured to display an image using one or both of first light reflected by the first display element and second light emitted by the second display element.

The first pixels and the second pixels are arranged at the same intervals in a display region. The first pixel and the second pixel each include subpixels exhibiting light of three colors of red (R), green (G), and blue (B). Furthermore, in the display portion, switching between a first display mode in which an image is displayed by the first pixels, a second display mode in which an image is displayed by the second pixels, and a third display mode in which an image is displayed by the first pixels and the second pixels can be performed.

Note that the liquid crystal operation mode of the first display element is a twisted nematic ECB mode, where external light is condensed using a diffusing film.

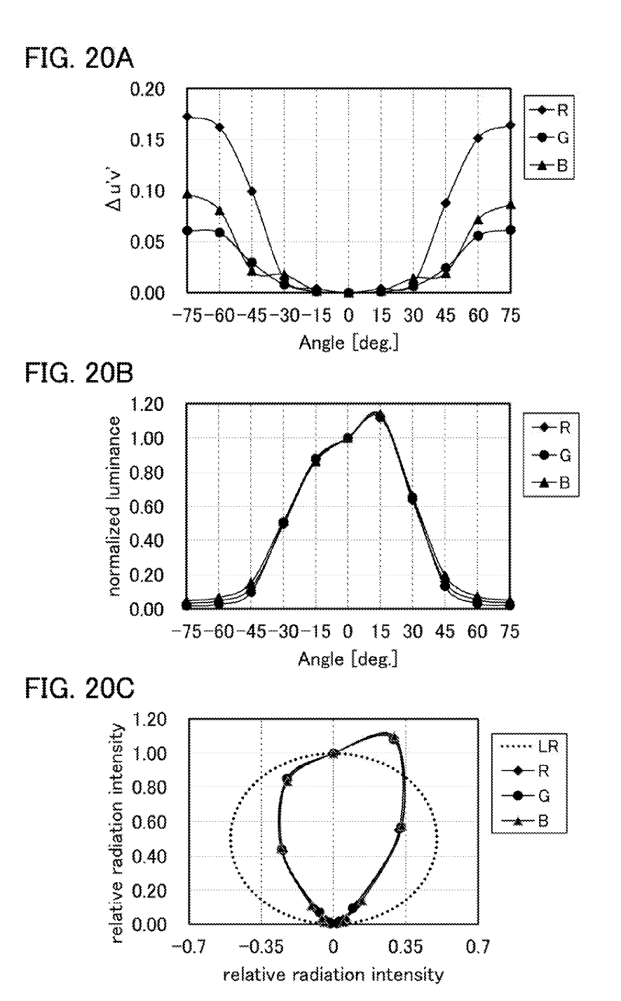

FIGS. 20A to 20C show measurement results of the viewing angle dependence of the display device in the first display mode.

The viewing angle dependence in the first display mode was measured in the following manner. The direction perpendicular to the surface of the display portion is regarded as 0°, and light from the direction of 0° is made to enter the display portion. The luminance spectra were measured at ten points at acceptance angles of −75°, −60°, −45°, −30°, −15°, 15°, 30°, 45°, 60°, and 75°. Then, the chromaticity at each angle was calculated using the spectra. The luminance spectra were measured for three colors of RGB on the display portion. In addition, the luminance spectra were measured at a position located in a direction perpendicular to the direction in which pixels of the same color are arranged in the display portion.

FIG. 20A shows the viewing angle dependence of the chromaticity, where the horizontal axis represents the angle and the vertical axis represents the rate of change in chromaticity using the data at 0° as a reference. FIG. 20B shows the viewing angle dependence of the luminance, where the horizontal axis represents the angle and the vertical axis represents the normalized luminance using the data at 0° as 1. FIG. 20C shows the viewing angle dependence of the radiation intensity represented in the polar coordinate space, where the vertical and horizontal axes represent the relative radiation intensity using the data at 0° as a reference. Note that because the light projection angle is 0° and thus the value at an acceptance angle of 0° cannot be obtained in the first display mode, the data at 0° in FIGS. 20A to 20C is the average of the measured values at −15° and 15°. A dotted line in FIG. 20C shows the Lambertian reflectance.

According to FIG. 20A, the rate of change in chromaticity (Δu′v′) is higher than 0.05 at the angles of −60° or less and 60° or more in the first display mode. In addition, the luminance at the angles of −45° or less and 45° or more in the case where the first display element is regarded as a secondary light source is less than or equal to approximately 10% of that at 0° (see FIG. 20B).

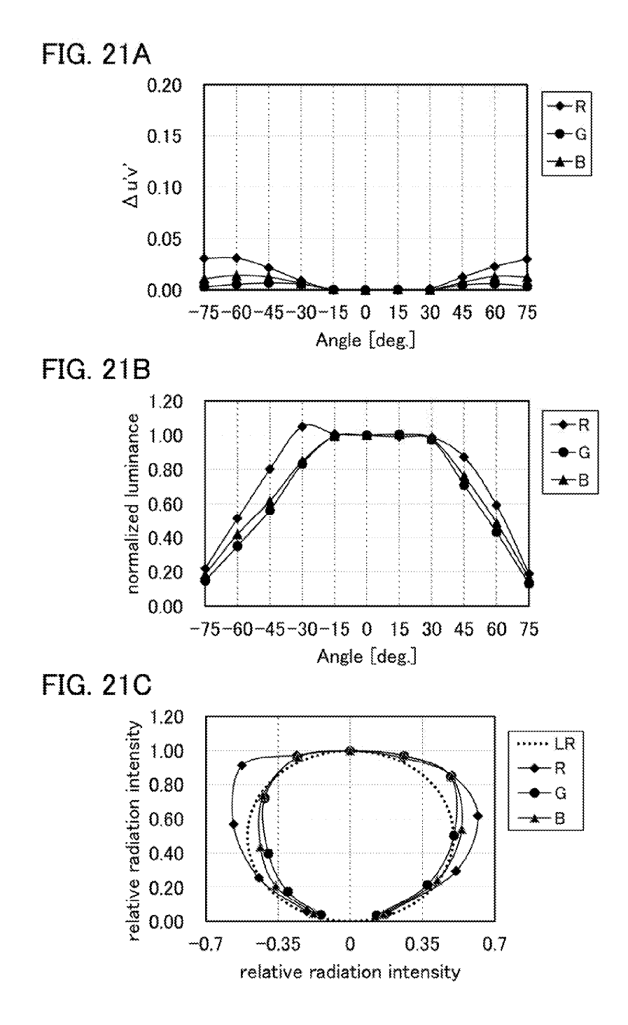

Next, FIGS. 21A to 21C show measurement results of the viewing angle dependence of the display device in the second display mode.

The viewing angle dependence in the second display mode was measured in the following manner. The direction perpendicular to the surface of the display portion is regarded as 0°, and light from the direction of 0° is made to enter the display portion.

The luminance spectra were measured at eleven points at acceptance angles of −75°, −60°, −45°, −30°, −15°, 0°, 15°, 30°, 45°, 60°, and 75°. Then, the chromaticity at each angle was calculated using the spectra. The luminance spectra were measured for three colors of RGB on the display portion. In addition, the luminance spectra were measured at a position located in a direction perpendicular to the direction in which pixels of the same color are arranged in the display portion.

FIGS. 21A, 21B, and 21C show the viewing angle dependence of the chromaticity, the viewing angle dependence of the luminance, and the viewing angle dependence of the radiation intensity, respectively.

According to FIG. 21A, the rate of change in chromaticity (Δu′v′) is lower than 0.05 at the angles of −60° or less and 60° or more in the second display mode. In addition, the luminance at the angles of −45° or less and 45° or more in the second display mode is more than approximately 10% of that at 0° (see FIG. 21B).

According to FIGS. 20A to 20C and FIGS. 21A to 21C, the second display mode has lower viewing angle dependence than the first display mode. The first display mode enables the display with not only low power consumption but also high visibility because high luminance display is possible under bright external light. The results shown in FIGS. 20A to 20C and FIGS. 21A to 21C indicate that the third display mode in which the second display element is supplementally used in addition to the first display element enables reduced viewing angle dependence and high display quality. Furthermore, changing the luminance of the image displayed by the second display element in accordance with the angle can further reduce the viewing angle dependence in the third display mode.

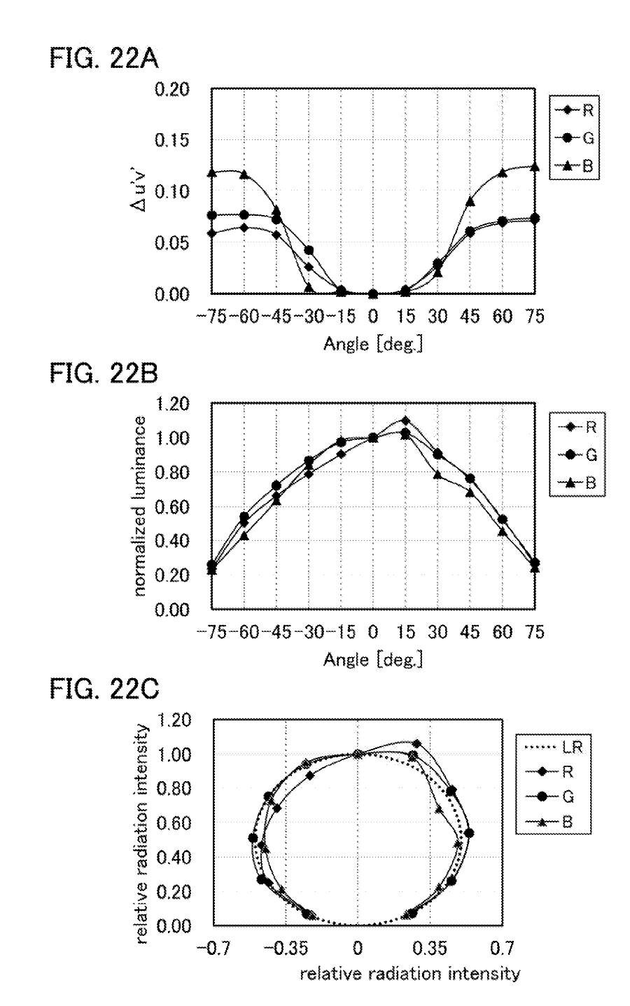

FIGS. 22A to 22C show measurement results of the viewing angle dependence of the display device in the third display mode in which the luminance of the image displayed by the second display element is adjusted in accordance with the angle.

The viewing angle dependence in the third display mode was measured in the following manner. The direction perpendicular to the surface of the display portion is regarded as 0°, and light from the direction of 0° is made to enter the display portion. The luminance spectra in the third display mode were measured at ten points at acceptance angles of −75°, −60°, −45°, −30°, −15°, 15°, 30°, 45°, 60°, and 75°. At this time, the measurement was performed while the luminance of the image displayed by the second display element was changed so that the viewing angle dependence of the radiation intensity could become as close as possible to the Lambertian reflectance. The luminance of the image displayed by the second display element was adjusted by changing the data amplitude. The data amplitude which was set so that the viewing angle dependence of the radiation intensity based on the luminance spectra measured at the various acceptance angles could become as close as possible to the Lambertian reflectance was recorded. The luminance spectra were measured for three colors of RGB on the display portion. Then, the chromaticity at each angle was calculated using the spectra. In addition, the luminance spectra were measured at a position located in a direction perpendicular to the direction in which pixels of the same color are arranged in the display portion.

FIGS. 22A, 22B, and 22C are graphs showing the viewing angle dependence of the chromaticity, the viewing angle dependence of the luminance, and the viewing angle dependence of the radiation intensity, respectively. Note that because the light projection angle is 0° and thus the value at an acceptance angle of 0° cannot be obtained in the third display mode, the data at 0° in FIGS. 22A to 22C is the average of the measured values at −15° and 15°.

According to FIGS. 20A and 20B and FIGS. 22A and 22B, the third display mode has lower viewing angle dependence than the first display mode. It is found from FIG. 22C that the viewing angle dependence of the radiation intensity in the third display mode is relatively close to the Lambertian reflectance.

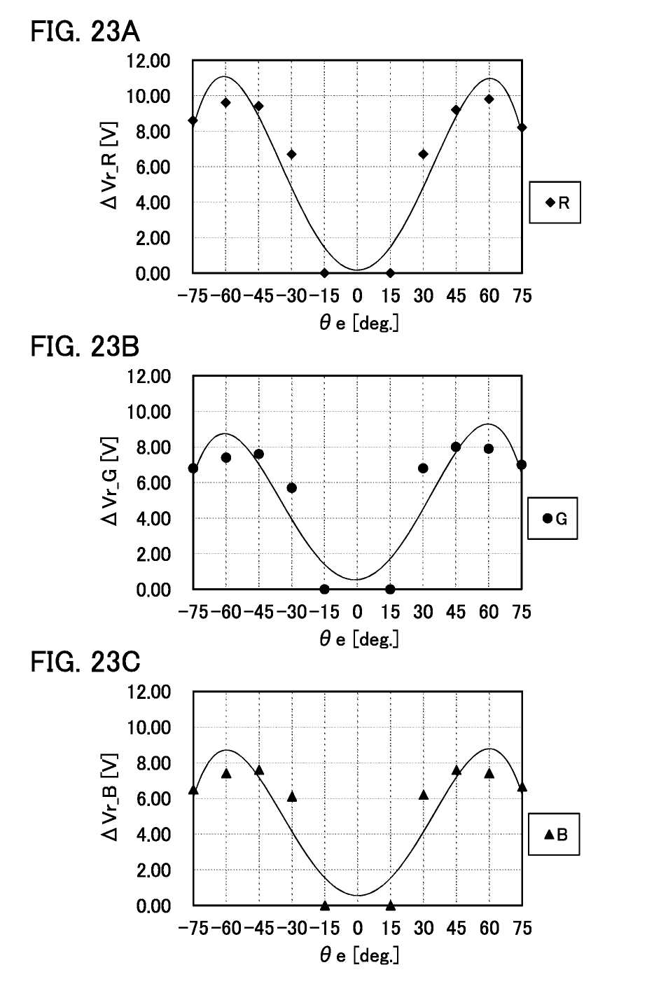

FIGS. 23A to 23C are graphs in which the data amplitudes recorded by the above measurement are plotted. FIGS. 23A to 23C show data amplitudes for R, G, and B. The horizontal axis represents the angle corresponding to the acceptance angle in the above measurement and the angle from which the display portion is viewed by the user in Embodiment 1, and the vertical axis represents the amount of change in the positive direction from the data amplitude at an acceptance angle of 0°. Furthermore, in each of FIGS. 23A to 23C, a function obtained from the plotted data amplitudes by polynomial approximation is shown by a solid line. When the angle θe in the horizontal axis is represented by x, the functions f_{R}(x), f_{G}(x), and f_{B}(x) shown in FIGS. 23A to 23C can be expressed by Equation 1 to Equation 3 below. Note that the coefficients in the terms in Equation 1 to Equation 3 are expressed by two significant figures.

(Equation 1)

f_{R}(x)=8.0×10⁻⁷x⁴−5.1×10⁻⁷x³+5.9×10⁻³x²+9.4×10⁻⁴x+0.17 (1)

(Equation 2)

f_{G}(x)=6.4×10⁻⁷x⁴−1.8×10⁻⁶x³+4.7×10⁻³x²+1.1×10⁻²x+0.54 (2)

(Equation 3)

f_{B}(x)=6.3×10⁻⁷x⁴+1.6×10⁻⁷x³+4.6×10⁻³x²−9.1×10⁻⁶x+0.55 (3)

For example, by adjusting the data amplitudes using the functions obtained in this example, the electronic device of one embodiment of the present invention described in Embodiment 1 can display an image with the viewing angle dependence reduced even when the angle from which the display portion is viewed by the user is changed.

This application is based on Japanese Patent Application serial no. 2016-149748 filed with Japan Patent Office on Jul. 29, 2016, the entire contents of which are hereby incorporated by reference.

What is claimed is:

1. A driving method of an electronic device comprising a display portion and a position detection sensor, the display portion comprising a first display element and a second display element,
wherein the first display element is configured to reflect a first light,
wherein the second display element is configured to emit a second light,
wherein the display portion is configured to display an image using one or both of the first light and the second light,
wherein the position detection sensor is configured to detect a position of a user, and
wherein, when the display portion displays the image using both the first light and the second light, an amount of the second light is adjusted in accordance with an angle from which the display portion is viewed by the user.

2. The driving method of an electronic device, according to claim 1,
wherein the electronic device comprises a housing, and
wherein the display portion and the position detection sensor are positioned on a first surface of the housing.

3. The driving method of an electronic device, according to claim 1,
wherein the first display element is a reflective liquid crystal element, and
wherein the second display element is a light-emitting element.

4. The driving method of an electronic device, according to claim 1,
wherein the amount of the second light is adjusted by an adjustment of data amplitude.

5. A driving method of an electronic device comprising a display portion, a position detection sensor, and an illuminance sensor, the display portion comprising a first display element and a second display element,
wherein the first display element is configured to reflect a first light,
wherein the second display element is configured to emit a second light,
wherein the display portion is configured to display an image using one or both of the first light and the second light,
wherein the position detection sensor is configured to detect a position of a user,
wherein the illuminance sensor is configured to measure an illuminance of external light, and
wherein, when the display portion displays the image using both the first light and the second light, an amount of the second light is adjusted in accordance with an angle from which the display portion is viewed by the user and the illuminance of the external light.

6. The driving method of an electronic device, according to claim 5,
wherein the electronic device comprises a housing, and
wherein the display portion, the position detection sensor, and the illuminance sensor are positioned on a first surface of the housing.

7. The driving method of an electronic device, according to claim 5,
wherein the first display element is a reflective liquid crystal element, and
wherein the second display element is a light-emitting element.

8. The driving method of an electronic device, according to claim 5,
wherein the amount of the second light is adjusted by an adjustment of data amplitude.

9. An electronic device comprising:
a display portion comprising:
a first display element configured to reflect a first light; and
a second display element configured to emit a second light;
a position detection sensor; and
a housing,
wherein the display portion and the position detection sensor are provided on a first surface of the housing,
wherein the display portion is configured to display an image using one or both of the first light and the second light, and
wherein the position detection sensor is configured to detect a position of a part of a user.

10. The electronic device according to claim 9, further comprising:
an illuminance sensor positioned on the first surface of the housing,
wherein the illuminance sensor is configured to measure an illuminance of external light.

11. The electronic device according to claim 9,
wherein the first display element is a reflective liquid crystal element, and
wherein the second display element is a light-emitting element.

12. The electronic device according to claim 9,
wherein, when the display portion displays the image using both the first light and the second light, an amount of the second light is adjusted in accordance with data detected by the position detection sensor.
